(19) United States
(12) Patent Application Publication
(10) Pub. No.: US 2026/0082582 A1
(43) Pub. Date: Mar. 19, 2026

(54) MAGNETIC MEMORY DEVICE AND METHOD OF MANUFACTURING THE MAGNETIC MEMORY DEVICE

(71) Applicant: Kioxia Corporation, Tokyo (JP)

(72) Inventors: Takuya SHIMANO, Seoul (KR); Kenichi YOSHINO, Seongnam-si Gyeonggi-do (KR)

(73) Assignee: Kioxia Corporation, Tokyo (JP)

(21) Appl. No.: 19/074,642

(22) Filed: Mar. 10, 2025

(30) Foreign Application Priority Data
Sep. 13, 2024 (JP) 2024-159387

(51) Int. Cl. H10B 61/00; H10N 50/01; H10N 50/10

(52) U.S. Cl. CPC H10B 61/10; H10N 50/01; H10N 50/10

(57) ABSTRACT

According to one embodiment, a magnetic memory device includes: a first wiring extending in a first direction; a second wiring extending in a second direction intersecting the first direction and provided above the first wiring; a first memory cell provided between the first wiring and the second wiring; a third wiring extending in the first direction and provided above the second wiring; and a second memory cell provided between the second wiring and the third wiring. The first memory cell includes a first selector body, a first conductor, and a first MTJ body provided on an upper surface of the first conductor. The second memory cell includes a second selector body, a second conductor, and a second MTJ body provided on an upper surface of the second conductor. The upper surface of the first conductor is flattened.

### CROSS-REFERENCE TO RELATED APPLICATIONS

This application is based upon and claims the benefit of priority from Japanese Patent Application No. 2024-159387, filed Sep. 13, 2024, the entire contents of which are incorporated herein by reference.

### FIELD

Embodiments described herein relate generally to a magnetic memory device and a method of manufacturing the magnetic memory device.

### BACKGROUND

A magnetic memory device (MRAM: Magnetoresistive Random Access Memory) using a magnetoresistive effect element as a memory element is known. The magnetoresistive effect element is connected in series with a switching element and functions as a memory cell.

### BRIEF DESCRIPTION OF DRAWINGS

FIG. 1 is a block diagram illustrating an example of a configuration of a magnetic memory device according to a first embodiment.

FIG. 2 is a circuit diagram illustrating an example of a circuit configuration of a memory cell array included in the magnetic memory device according to the first embodiment.

FIG. 3 is a perspective view illustrating an example of a three-dimensional structure of the memory cell array included in the magnetic memory device according to the first embodiment.

FIG. 4 is a cross-sectional view illustrating an example of a cross-sectional structure of the memory cell array included in the magnetic memory device according to the first embodiment.

FIG. 5 is a cross-sectional view illustrating an example of the cross-sectional structure of the memory cell array included in the magnetic memory device according to the first embodiment.

FIG. 6 is a cross-sectional view illustrating an example of a cross-sectional structure of a magnetoresistive effect element included in the magnetic memory device according to the first embodiment.

FIG. 7 is a flow chart illustrating an example of a method of manufacturing the memory cell array in the magnetic memory device according to the first embodiment.

FIG. 8 is a cross-sectional view for explaining an example of the method of manufacturing the memory cell array in the magnetic memory device according to the first embodiment.

FIG. 9 is a cross-sectional view for explaining an example of the method of manufacturing the memory cell array in the magnetic memory device according to the first embodiment.

FIG. 10 is a cross-sectional view for explaining an example of the method of manufacturing the memory cell array in the magnetic memory device according to the first embodiment.

FIG. 11 is a cross-sectional view for explaining an example of the method of manufacturing the memory cell array in the magnetic memory device according to the first embodiment.

FIG. 12 is a cross-sectional view for explaining an example of the method of manufacturing the memory cell array in the magnetic memory device according to the first embodiment.

FIG. 13 is a cross-sectional view for explaining an example of the method of manufacturing the memory cell array in the magnetic memory device according to the first embodiment.

FIG. 14 is a cross-sectional view for explaining an example of the method of manufacturing the memory cell array in the magnetic memory device according to the first embodiment.

FIG. 15 is a cross-sectional view for explaining an example of the method of manufacturing the memory cell array in the magnetic memory device according to the first embodiment.

FIG. 16 is a cross-sectional view for explaining an example of the method of manufacturing the memory cell array in the magnetic memory device according to the first embodiment.

FIG. 17 is a cross-sectional view for explaining an example of the method of manufacturing the memory cell array in the magnetic memory device according to the first embodiment.

FIG. 18 is a cross-sectional view for explaining an example of the method of manufacturing the memory cell array in the magnetic memory device according to the first embodiment.

FIG. 19 is a cross-sectional view for explaining an example of the method of manufacturing the memory cell array in the magnetic memory device according to the first embodiment.

FIG. 20 is a cross-sectional view for explaining an example of the method of manufacturing the memory cell array in the magnetic memory device according to the first embodiment.

FIG. 21 is a cross-sectional view for explaining an example of the method of manufacturing the memory cell array in the magnetic memory device according to the first embodiment.

FIG. 22 is a cross-sectional view for explaining an example of the method of manufacturing the memory cell array in the magnetic memory device according to the first embodiment.

FIG. 23 is a cross-sectional view for explaining an example of the method of manufacturing the memory cell array in the magnetic memory device according to the first embodiment.

FIG. 24 is a cross-sectional view for explaining an example of the method of manufacturing the memory cell array in the magnetic memory device according to the first embodiment.

FIG. 25 is a cross-sectional view illustrating an example of a cross-sectional structure of a memory cell array included in a magnetic memory device according to a second embodiment.

FIG. 26 is a cross-sectional view illustrating an example of the cross-sectional structure of the memory cell array included in the magnetic memory device according to the second embodiment.

FIG. 27 is a flow chart illustrating an example of a method of manufacturing the memory cell array in the magnetic memory device according to the second embodiment.

FIG. 28 is a cross-sectional view for explaining an example of the method of manufacturing the memory cell array in the magnetic memory device according to the second embodiment.

FIG. 29 is a cross-sectional view for explaining an example of the method of manufacturing the memory cell array in the magnetic memory device according to the second embodiment.

FIG. 30 is a cross-sectional view for explaining an example of the method of manufacturing the memory cell array in the magnetic memory device according to the second embodiment.

FIG. 31 is a cross-sectional view for explaining an example of the method of manufacturing the memory cell array in the magnetic memory device according to the second embodiment.

FIG. 32 is a cross-sectional view for explaining an example of the method of manufacturing the memory cell array in the magnetic memory device according to the second embodiment.

FIG. 33 is a cross-sectional view for explaining an example of the method of manufacturing the memory cell array in the magnetic memory device according to the second embodiment.

FIG. 34 is a cross-sectional view for explaining an example of the method of manufacturing the memory cell array in the magnetic memory device according to the second embodiment.

FIG. 35 is a cross-sectional view for explaining an example of the method of manufacturing the memory cell array in the magnetic memory device according to the second embodiment.

FIG. 36 is a cross-sectional view for explaining an example of the method of manufacturing the memory cell array in the magnetic memory device according to the second embodiment.

FIG. 37 is a cross-sectional view for explaining an example of the method of manufacturing the memory cell array in the magnetic memory device according to the second embodiment.

FIG. 38 is a cross-sectional view for explaining an example of the method of manufacturing the memory cell array in the magnetic memory device according to the second embodiment.

FIG. 39 is a cross-sectional view for explaining an example of the method of manufacturing the memory cell array in the magnetic memory device according to the second embodiment.

FIG. 40 is a cross-sectional view for explaining an example of the method of manufacturing the memory cell array in the magnetic memory device according to the second embodiment.

### DETAILED DESCRIPTION

In general, according to one embodiment, a magnetic memory device includes: a first wiring extending in a first direction; a second wiring extending in a second direction intersecting the first direction and provided above the first wiring; a first memory cell provided between the first wiring and the second wiring; a third wiring extending in the first direction and provided above the second wiring; and a second memory cell provided between the second wiring and the third wiring. The first memory cell includes a first selector body, a first conductor, and a first MTJ body provided on an upper surface of the first conductor. The second memory cell includes a second selector body, a second conductor, and a second MTJ body provided on an upper surface of the second conductor. The upper surface of the first conductor is flattened.

Embodiments will be described below with reference to the drawings. The embodiments exemplify a device and method that realize the technical concept of the invention. The drawings are schematic or conceptual. Dimensions, ratios, and the like of the drawings are not necessarily the same as actual ones. Illustration of the configuration is omitted as appropriate. Hatching added to the plan views is not necessarily associated with a material or a characteristic of a component. In the present specification, components having substantially the same functions and configurations will be referred to by the same reference symbols. Numbers, characters, and the like added to reference symbols are referred to by the same reference symbols, and are used to distinguish between similar elements. In addition, in the present specification, a “stacked film including A/B” indicates a stacked structure of a film including an element A and a film including an element B.

### 1. First Embodiment

A magnetic memory device according to a first embodiment will be described. The magnetic memory device according to the first embodiment includes, for example, a perpendicularly magnetized magnetic memory device using an element having a magnetoresistance effect due to magnetic tunnel junction (MTJ) as a resistance changing element.

Note that, in the following description, the resistance changing element is also referred to as a magnetoresistive effect element (MTJ).

### 1.1 Configuration

First, a configuration of the magnetic memory device according to the first embodiment will be described.

### 1.1.1 Configuration of Magnetic Memory Device

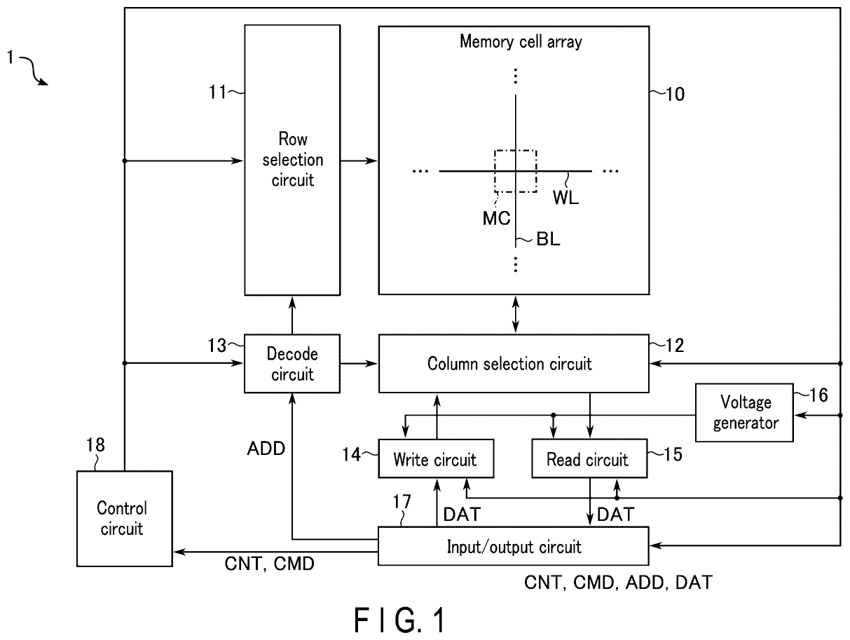

FIG. 1 is a block diagram illustrating an example of the configuration of the magnetic memory device according to the first embodiment. As illustrated in FIG. 1, a magnetic memory device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC each associated with a pair of a row and a column. The memory cells MC in the same row are connected to the same word line WL. The memory cells MC in the same column are connected to the same bit line BL.

The row selection circuit 11 is connected to the memory cell array 10 via a word line WL. To the row selection circuit 11, a decode result (row address) of an address ADD from the decode circuit 13 is supplied. The row selection circuit 11 sets the word line WL corresponding to a row based on the decode result of the address ADD to a selected state.

The column selection circuit 12 is connected to the memory cell array 10 via the bit line BL. To the column selection circuit 12, a decode result (column address) of the address ADD from the decode circuit 13 is supplied.

The column selection circuit 12 sets the bit line BL corresponding to a column based on the decode result of the address ADD to the selected state.

The decode circuit 13 decodes the address ADD from the input/output circuit 17. The decode circuit 13 supplies the decode result of the address ADD to the row selection circuit 11 and the column selection circuit 12. The address ADD includes a row address and a column address to be selected.

The write circuit 14 writes data to the memory cell MC. The write circuit 14 includes, for example, a write driver (not illustrated).

The read circuit 15 reads data from the memory cell MC. The read circuit 15 includes, for example, a sense amplifier (not illustrated).

The voltage generator 16 generates a voltage for various operations of the memory cell array 10 using a power supply voltage supplied from a device (not illustrated) outside the magnetic memory device 1. For example, the voltage generator 16 generates various voltages necessary for a write operation and outputs the voltages to the write circuit 14. In addition, for example, the voltage generator 16 generates various voltages necessary for a read operation and outputs the voltages to the read circuit 15.

The input/output circuit 17 manages communication with the outside of the magnetic memory device 1. The input/output circuit 17 transfers the address ADD from the outside of the magnetic memory device 1 to the decode circuit 13. The input/output circuit 17 transfers a control signal CNT and a command CMD from the outside of the magnetic memory device 1 to the control circuit 18.

The input/output circuit 17 transfers data DAT from the outside of the magnetic memory device 1 to the write circuit 14, and outputs the data DAT transferred from the read circuit 15 to the outside of the magnetic memory device 1.

The control circuit 18 controls operations of the row selection circuit 11, the column selection circuit 12, the decode circuit 13, the write circuit 14, the read circuit 15, the voltage generator 16, and the input/output circuit 17 in the magnetic memory device 1 based on the control signal CNT and the command CMD.

### 1.1.2 Configuration of Memory Cell Array

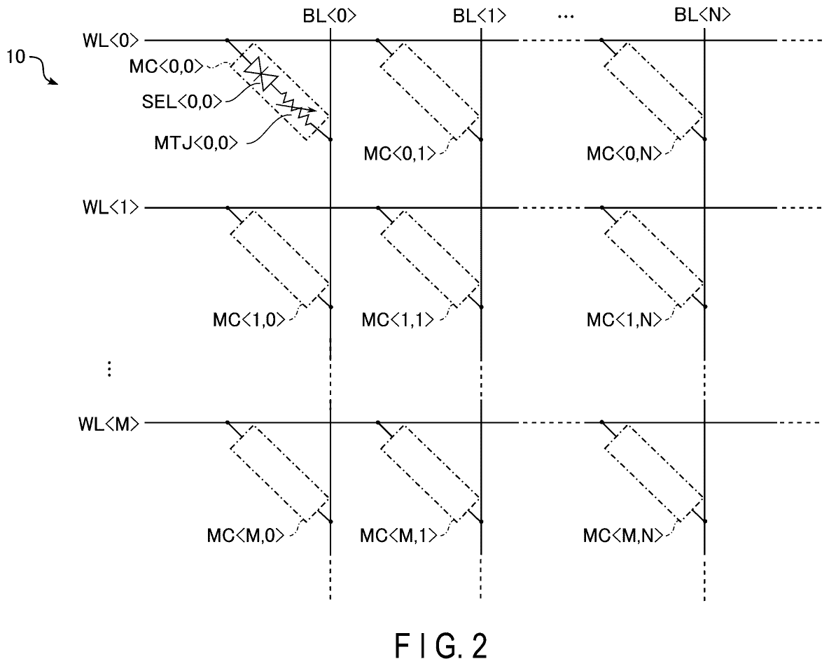

Next, a configuration of the memory cell array 10 of the magnetic memory device 1 according to the first embodiment will be described with reference to FIG. 2.

FIG. 2 is a circuit diagram illustrating an example of a circuit configuration of the memory cell array 10 included in the magnetic memory device 1 according to the first embodiment. In FIG. 2, the word line WL and the bit line BL are classified by subscripts including indexes “< >”.

As illustrated in FIG. 2, the memory cells MC are arranged in a matrix in the memory cell array 10, and are associated with a pair of one of the plurality of bit lines BL (BL<0>, BL<1>, . . . , BL<N>) and one of the plurality of word lines WL (WL<0>, WL<1>, . . . , WL<M>) (M and N are natural numbers). That is, the memory cell MC<i, j>(0≤i≤M, 0≤j≤N) is connected between the word line WL<i> and the bit line BL<j>.

The memory cell MC<i, j>includes a switching element SEL<i, j> and a magnetoresistive effect element MTJ<i, j> connected in series.

The switching element SEL is a two-terminal switching element. A two-terminal switching element is different from a three-terminal switching element such as a transistor in that it does not include a third terminal.

In a case where a voltage applied between the two terminals is less than a threshold voltage Vth (voltage applied between the two terminals<threshold voltage Vth), the switching element SEL is in a high resistance state. The high resistance state is, for example, an “off” state, which is an electrically non-conductive state. In a case where a voltage applied between the two terminals is equal to or higher than the threshold voltage Vth (voltage applied between the two terminals≥threshold voltage Vth), the switching element SEL is in a low resistance state. The low resistance state is, for example, an “on” state, which is an electrically conductive state. More specifically, for example, in a case where a voltage applied to the corresponding memory cell MC is less than the threshold voltage Vth (voltage applied to the corresponding memory cell MC<threshold voltage Vth), the switching element SEL blocks a current as an insulator having a large resistance value. That is, the switching element SEL is in the off state. In a case where a voltage applied to the corresponding memory cell MC is equal to or higher than the threshold voltage Vth (voltage applied to the corresponding memory cell MC≥threshold voltage Vth), the switching element SEL lets a current pass therethrough as a conductor having a small resistance value. That is, the switching element SEL is in the on state. The switching element SEL switches whether to let a current pass therethrough or block the current depending on the magnitude of the voltage applied to the corresponding memory cell MC regardless of the polarity of the voltage applied between the two terminals (regardless of the direction of the current flowing).

The magnetoresistive effect element MTJ is in a low resistance state or a high resistance state depending on a current controlled by the switching element SEL. That is, the resistance state of the magnetoresistive effect element MTJ can be switched between the low resistance state and the high resistance state based on the current controlled by the switching element SEL. The magnetoresistive effect element MTJ can write data based on a change in its resistance state, holds the written data in a nonvolatile manner, and functions as a readable storage element.

### 1.1.3 Structure of Memory Cell Array

Next, a structure of the memory cell array 10 of the magnetic memory device 1 according to the first embodiment will be described. In the following description, an xyz Cartesian coordinate system is used. An X direction corresponds to an extending direction of the word line WL. A Y direction corresponds to an extending direction of the bit line BL. A Z direction corresponds to a vertical direction to a surface of a semiconductor substrate used for forming the magnetic memory device 1. The description “below”, and its derivatives and related words indicate a position with smaller coordinates on a Z axis. The description “above”, and its derivatives and related words indicate a position with larger coordinates on the Z axis. Hatching is added as appropriate to the perspective views. The hatching added to the perspective views is not necessarily associated with a material or a characteristic of the component to which the hatching is added. In the perspective views and the cross-sectional views, illustration of a configuration of an interlayer insulating film or the like is omitted.

### 1.1.3.1 Three-dimensional Structure of Memory Cell Array

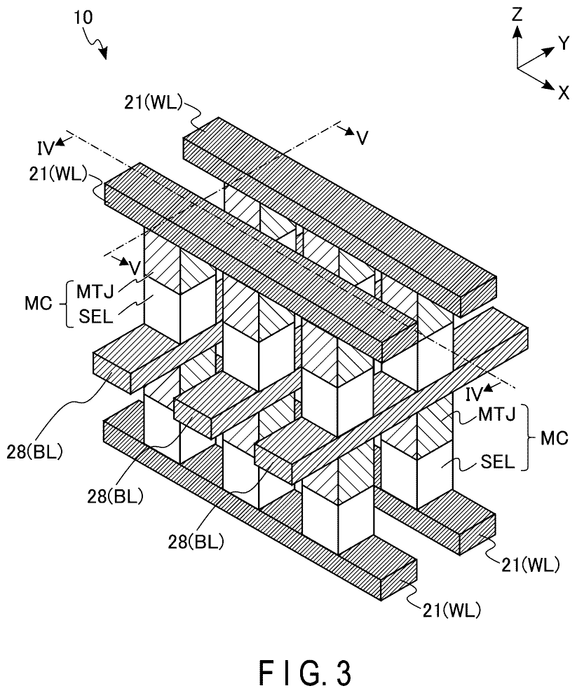

An example of a three-dimensional structure of the memory cell array 10 will be described with reference to FIG. 3. FIG. 3 is a perspective view illustrating an example of a three-dimensional structure of the memory cell array 10 included in the magnetic memory device 1 according to the first embodiment.

The memory cell array 10 is provided above the semiconductor substrate (not illustrated).

As illustrated in FIG. 3, the memory cell array 10 includes a plurality of conductors (wirings) 21, a plurality of conductors (wirings) 28, and the plurality of memory cells MC.

The plurality of conductors 28 are provided above the plurality of conductors 21. The plurality of conductors 21 are provided above the plurality of conductors 28.

Each of the plurality of conductors 21 has a portion extending in the X direction. The plurality of conductors 21 are arrayed in the Y direction and are separated from each other. Each conductor 21 is used as the word line WL. Each of the plurality of conductors 28 has a portion extending in the Y direction. The plurality of conductors 28 are arrayed in the X direction and are separated from each other. Each conductor 28 is used as the bit line BL. The conductor 21 and the conductor 28 are provided apart from each other in the Z direction. One memory cell MC is provided at each of portions where the plurality of conductors 21 and the plurality of conductors 28 intersect. In other words, each memory cell MC is provided in a columnar shape between the associated word line WL and bit line BL. The memory cell MC has, for example, a structure in which the switching element SEL is provided below the magnetoresistive effect element MTJ. That is, a structure in which the switching element SEL, which is a selector body SEL, and the magnetoresistive effect element MTJ, which is a magnetoresistive effect element layer (MTJ body), are stacked is formed.

The memory cell array 10 has a plurality of structures each including the conductor 21, the conductor 28, and the memory cell MC provided therebetween (hereinafter, referred to as a “stacked structure”).

Hereinafter, the plurality of stacked structures are referred to as a “first-stage stacked structure” and a “second-stage stacked structure” in order from the bottom. The first-stage stacked structure has a structure in which the conductor 21, the memory cell MC, and the conductor 28 are stacked in this order. The second-stage stacked structure has a structure in which the conductor 28, the memory cell MC, and the conductor 21 are stacked in this order.

Note that the memory cell MC may have a structure in which the selector body SEL that is the switching element SEL is provided above the magnetoresistive effect element layer (MTJ body) that is the magnetoresistive effect element MTJ. In the following description, the switching element SEL is referred to as the selector body SEL, and the magnetoresistive effect element MTJ is referred to as the MTJ body. In addition, the first-stage stacked structure may have a structure in which the conductor 28, the memory cell MC, and the conductor 21 are stacked in this order, and the second-stage stacked structure may have a structure in which the conductor 21, the memory cell MC, and the conductor 28 are stacked in this order.

### 1.1.3.2 Cross-sectional Structure of Memory Cell Array

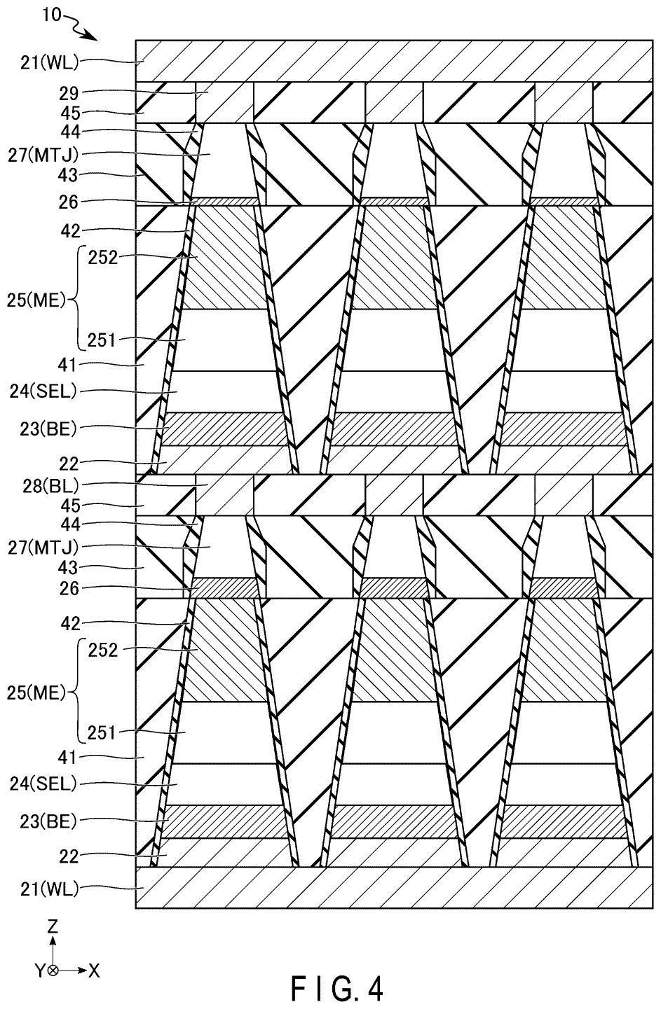

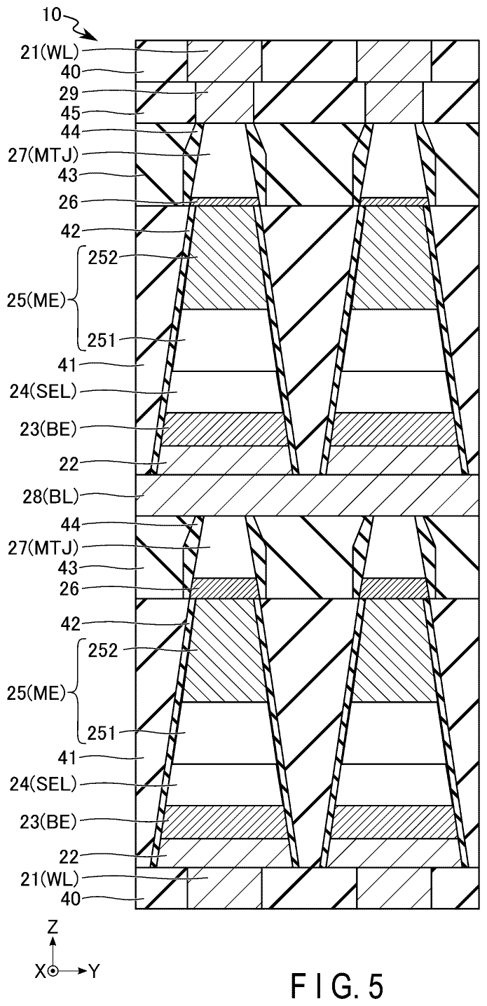

An example of a cross-sectional structure of the memory cell array 10 will be described with reference to FIGS. 4 and 5. FIG. 4 is a cross-sectional view taken along line IV-IV in FIG. 3, illustrating an example of a cross-sectional structure of the memory cell array 10 included in the magnetic memory device 1 according to the first embodiment. FIG. 5 is a cross-sectional view taken along line V-V in FIG. 3, illustrating an example of the cross-sectional structure of the memory cell array 10 included in the magnetic memory device 1 according to the first embodiment.

As illustrated in FIGS. 4 and 5, the memory cell array 10 includes the plurality of conductors 21, a plurality of conductors 22, a plurality of electrodes 23, a plurality of selector bodies 24, a plurality of electrodes 25, a plurality of conductors 26, a plurality of MTJ bodies 27, the plurality of conductors 28, a plurality of conductors 29, an insulator 40, an insulator 41, a plurality of insulators 42, an insulator 43, a plurality of insulators 44, and an insulator 45.

For example, the plurality of conductors 21 are provided above the semiconductor substrate (not illustrated). The plurality of conductors 21 are arrayed along the Y direction. Each of the plurality of conductors 21 extends along the X direction. Each of the plurality of conductors 21 has conductivity and functions as the word line WL.

The insulator 40 is provided in a region between two conductors 21 adjacent to each other in the Y direction.

Due to this, each of the plurality of conductors 21 is insulated from each other in the Y direction. The insulator 40 is formed of an insulating material. The insulator 40 includes, for example, silicon oxide (SiO₂) or silicon nitride (SiN). Note that the insulator 40 may be formed of a plurality of insulating materials.

Note that the plurality of conductors 21 and the insulator 40 may be provided on an upper surface of the semiconductor substrate, or may be provided so as to be separated from the semiconductor substrate without being in contact with the semiconductor substrate.

The plurality of conductors 22 are provided on an upper surface of each of the plurality of conductors 21.

The plurality of conductors 22 provided on the upper surface of the same conductor 21 are arrayed in the X direction. Each of the plurality of conductors 22 has conductivity. One conductor 21 and the plurality of conductors 22 provided on the upper surface of the conductor 21 are also collectively referred to as the word line WL.

One corresponding electrode 23 among the plurality of electrodes 23 is provided on an upper surface of each of the plurality of conductors 22. Each of the plurality of electrodes 23 has conductivity and functions as a bottom electrode BE.

One corresponding selector body 24 among the plurality of selector bodies 24 is provided on an upper surface of each of the plurality of electrodes 23. Each of the plurality of selector bodies 24 functions as the switching element SEL.

One corresponding electrode 25 among the plurality of electrodes 25 is provided on an upper surface of each of the plurality of selector bodies 24. Each of the plurality of electrodes 25 functions as a middle electrode ME.

Details of the configuration of the electrode 25 will be described later.

Hereinafter, a structure including the conductor 22, the electrode 23, the selector body 24, and the electrode 25 is referred to as a “first layer stack”. The memory cell array 10 includes a plurality of first layer stacks. An insulator 42 (side wall) is provided on a side surface of each of the plurality of first layer stacks so as to cover the side surface. That is, the insulator 42 covers a side surface of the conductor 22, a side surface of the electrode 23, a side surface of the selector body 24, and a side surface of the electrode 25. The insulator 42 is provided, for example, from a position equivalent to the upper surface of the conductor 21 to a position equivalent to an upper surface of the electrode 25. Due to this, each of the plurality of conductors 22 is insulated from each other in the Y direction. Each of the plurality of electrodes 23 is insulated from each other. Each of the plurality of selector bodies 24 is insulated from each other. Each of the plurality of electrodes 25 is insulated from each other. The insulator 42 is formed of an insulating material. The insulator 42 includes, for example, silicon nitride. Note that the insulator 42 may be formed of a plurality of insulating materials.

The insulator 41 is provided in a region between two insulators 42 adjacent to each other. The insulator 41 is formed of an insulating material. The insulator 41 includes, for example, silicon oxide or silicon nitride.

Note that the insulator 41 may be formed of a plurality of insulating materials.

One corresponding conductor 26 among the plurality of conductors 26 is provided on the upper surface of each of the plurality of electrodes 25. Each of the plurality of conductors 26 has conductivity. Hereinafter, the conductor 26 is also referred to as a “buffer layer BF”. The buffer layer BF is a layer provided to cancel the crystallinity of the electrode 25 provided below the MTJ body 27. In other words, the buffer layer BF is a layer provided so that the crystallinity of the electrode 25 provided below the MTJ body 27 does not affect the crystallinity of each layer included in the MTJ body 27. For the conductor 26, a material that prevents the crystallinity of the electrode 25 from affecting the crystallinity of each layer included in the MTJ body 27 is used. The conductor 26 includes, for example, hafnium (Hf), hafnium boride (HfB), or the like. In addition, an upper surface of the conductor 26 is flattened. The thickness of the conductor 26 is, for example, about 3 nanometers (nm).

One corresponding MTJ body 27 among the plurality of MTJ bodies 27 is provided on the upper surface of each of the plurality of conductors 26. Each of the plurality of MTJ bodies 27 functions as a magnetoresistive effect element MTJ. Details of the configuration of the MTJ body 27 will be described later.

Hereinafter, a structure including the conductor 26 and the MTJ body 27 is referred to as a “second layer stack”. The memory cell array 10 includes a plurality of second layer stacks. An insulator 44 (side wall) is provided on a side surface of each of the plurality of second layer stacks so as to cover the side surface. That is, the insulator 44 covers a side surface of the conductor 26 and a side surface of the MTJ body 27. The insulator 44 is provided, for example, from a position equivalent to the upper surface of the electrode 25 to a position equivalent to an upper surface of the MTJ body 27. Due to this, each of the plurality of conductors 26 is insulated from each other. Each of the plurality of MTJ bodies 27 is insulated from each other. The insulator 44 is formed of an insulating material. The insulator 44 includes, for example, silicon nitride. Note that the insulator 44 may be formed of a plurality of insulating materials.

The insulator 43 is provided in a region between two insulators 44 adjacent to each other. The insulator 43 is formed of an insulating material. The insulator 43 includes, for example, silicon oxide or silicon nitride.

Note that the insulator 43 may be formed of a plurality of insulating materials.

One conductor 28 extending in the Y direction is provided so as to be in contact with the upper surface of each of the plurality of MTJ bodies 27 arrayed in the Y direction. The plurality of conductors 28 are arrayed in the X direction. Each of the plurality of conductors 28 extends along the Y direction. Each of the plurality of conductors 28 has conductivity and functions as the bit line BL.

The insulator 45 is provided in a region between two conductors 28 adjacent to each other in the X direction.

Due to this, each of the plurality of conductors 28 is insulated from each other in the X direction. The insulator 45 is formed of an insulating material. The insulator 45 includes, for example, silicon oxide or silicon nitride. Note that the insulator 45 may be formed of a plurality of insulating materials.

A structure in which the conductor 21, the conductor 22, the electrode 23, the selector body 24, the electrode 25, the conductor 26, the MTJ body 27, and the conductor 28 are stacked in this order as described above corresponds to the first-stage stacked structure. The memory cell MC of the first-stage stacked structure includes the conductor 22, the electrode 23, the selector body 24, the electrode 25, the conductor 26, and the MTJ body 27. The electrode 25 is provided between the selector body 24 and the conductor 26.

In the first-stage stacked structure, the upper surface of the conductor 26 (buffer layer BF) with which a lower surface of the MTJ body 27 is in contact is flattened. Thus, the upper surface of each layer included in the MTJ body 27 provided on the upper surface of the conductor 26 is also flattened. Therefore, the MTJ body 27 has relatively good quality characteristics (for example, coercive force or the like).

In addition, in the first-stage stacked structure, the conductor 26 (buffer layer BF) is provided between the MTJ body 27 and the electrode 25. Due to this, the crystallinity of each layer included in the MTJ body 27 is not affected by the crystallinity of the electrode 25.

Therefore, the MTJ body 27 has a relatively good quality crystal structure.

The plurality of conductors 22 are provided on an upper surface of each of the plurality of conductors 28.

The plurality of conductors 22 provided on the upper surface of the same conductor 28 are arrayed in the Y direction. Each of the plurality of conductors 22 has conductivity. One conductor 28 and the plurality of conductors 22 provided on the upper surface of the conductor 28 are also collectively referred to as the bit line BL.

The electrode 23, the selector body 24, and the electrode 25 are provided on the upper surface of each of the plurality of conductors 22, as in the first-stage stacked structure. The structure of the electrode 25 is the same as that of the first-stage stacked structure. The insulator 42 is provided on the side surface of each of the plurality of first layer stack each including the conductor 22, the electrode 23, the selector body 24, and the electrode 25, as in the first-stage stacked structure. That is, the insulator 42 covers the side surface of the conductor 22, the side surface of the electrode 23, the side surface of the selector body 24, and the side surface of the electrode 25. The insulator 41 is provided in the region between two insulators 42 adjacent to each other, as in the first-stage stacked structure.

The conductor 26 (buffer layer BF) and the MTJ body 27 are provided on the upper surface of each of the plurality of electrodes 25, as in the first-stage stacked structure. The conductor 26 includes, for example, hafnium (Hf), hafnium boride (HfB), or the like. The thickness of the conductor 26 is, for example, about 1 nanometer (nm). The structure of the MTJ body 27 is the same as that of the first-stage stacked structure.

The insulator 44 is provided on the side surface of each of the plurality of second layer stacks each including the conductor 26 and the MTJ body 27, as in the first-stage stacked structure. That is, the insulator 44 covers the side surface of the conductor 26 and the side surface of the MTJ body 27. The insulator 43 is provided in the region between two insulators 44 adjacent to each other, as in the first-stage stacked structure.

One corresponding conductor 29 among the plurality of conductors 29 is provided on the upper surface of each of the plurality of MTJ bodies 27. The plurality of conductors 29 are arrayed in the X direction and the Y direction. Each of the plurality of conductors 29 has conductivity. The insulator 45 is provided in a region between two conductors 29 adjacent to each other. Due to this, each of the plurality of conductors 29 is insulated from each other.

One conductor 21 extending in the X direction is provided so as to be in contact with an upper surface of each of the plurality of conductors 29 arrayed in the X direction. The plurality of conductors 21 are arrayed in the Y direction. Each of the plurality of conductors 21 extends along the X direction. Each of the plurality of conductors 21 has conductivity and functions as the word line WL. One conductor 21 and the plurality of conductors 29 provided on a lower surface of the conductor 21 are also collectively referred to as the word line WL.

The insulator 40 is provided in the region between two conductors 21 adjacent to each other in the Y direction, as in the first-stage stacked structure. Due to this, each of the plurality of conductors 21 is insulated from each other in the Y direction.

A structure in which the conductor 28, the conductor 22, the electrode 23, the selector body 24, the electrode 25, the conductor 26, the MTJ body 27, the conductor 29, and the conductor 21 are stacked in this order as described above corresponds to the second-stage stacked structure. The memory cell MC of the second-stage stacked structure includes the conductor 22, the electrode 23, the selector body 24, the electrode 25, the conductor 26, the MTJ body 27, and the conductor 29. The electrode 25 is provided between the selector body 24 and the conductor 26.

The thickness of the conductor 26 included in the first-stage stacked structure is different from the thickness of the conductor 26 included in the second-stage stacked structure. For example, the thickness of the conductor 26 included in the first-stage stacked structure is thicker than the thickness of the conductor 26 included in the second-stage stacked structure. Note that the thickness of the conductor 26 included in the first-stage stacked structure may be thinner than the thickness of the conductor 26 included in the second-stage stacked structure.

The thickness of the conductor 26 included in the first-stage stacked structure is set in consideration of deterioration of the characteristics of the MTJ body 27 due to two annealing treatments to be described later.

Specifically, the annealing treatment is performed by changing the temperature, time, and number of times in advance, and the deterioration of the characteristics of the MTJ body 27 is acquired as data for each temperature, time, and number of times. Then, the thickness of the conductor 26 included in the first-stage stacked structure is set based on the acquired data.

In addition, in the second-stage stacked structure, the conductor 26 (buffer layer BF) is provided between the MTJ body 27 and the electrode 25. Due to this, the crystallinity of each layer included in the MTJ body 27 is not affected by the crystallinity of the electrode 25.

Therefore, the MTJ body 27 has a relatively good quality crystal structure.

Note that, in the second-stage stacked structure, the upper surface of the conductor 26 may be flattened. In this case, the upper surface of each layer included in the MTJ body 27 provided on the upper surface of the conductor 26 is also flattened. Therefore, the characteristics of the MTJ body 27 included in the second-stage stacked structure are improved.

### 1.1.4 Cross-sectional Structure of Middle Electrode

Next, an example of a cross-sectional structure of the middle electrode ME of the magnetic memory device 1 according to the first embodiment will be described with continued reference to FIGS. 4 and 5.

Each of the plurality of electrodes 25 includes conductors 251 and 252. Hereinafter, the conductor 251 is also referred to as a “sub-electrode 251”. The conductor 252 is also referred to as a “sub-electrode 252”.

The conductor 251 is provided on the upper surface of the selector body 24. The conductor 251 is formed of, for example, at least one element or compound selected from carbon (C) and carbon nitride (CN). The conductor 251 preferably has an amorphous structure. The thickness of the conductor 251 is, for example, 2 nanometers (nm) or more and 20 nanometers (nm) or less. In a case where the thickness of the conductor 251 is within such a range, peeling of the conductor 251 from the upper surface of the selector body 24 is suppressed.

Note that, in the present specification, a part “formed of” each element may include unintended impurities different from the element. The unintended impurities include, for example, an element included in a gas used in the manufacturing process of the magnetic memory device 1 and an element mixed into the part from the periphery of the part.

The conductor 252 is provided on an upper surface of the conductor 251. The conductor 252 is formed of, for example, at least one element or compound selected from high melting point metal elements and compounds of high melting point metal elements. In the present embodiment, the high melting point metal is, for example, a material having a melting point higher than that of iron (Fe) and cobalt (Co). Examples of the high melting point metal element and the compound of the high melting point metal element include titanium (Ti), tantalum (Ta), tungsten (W), titanium nitride (TiN), tantalum nitride (TaN), and tungsten nitride (WN). The conductor 252 has, for example, a crystal structure. The thickness of the conductor 252 is preferably, for example, 0.1 nanometers (nm) or more and 3 nanometers (nm) or less.

Note that the middle electrode ME is not limited to the structure in FIGS. 4 and 5. The middle electrode ME may include, for example, other layers.

### 1.1.5 Cross-sectional Structure of Magnetoresistive Effect Element

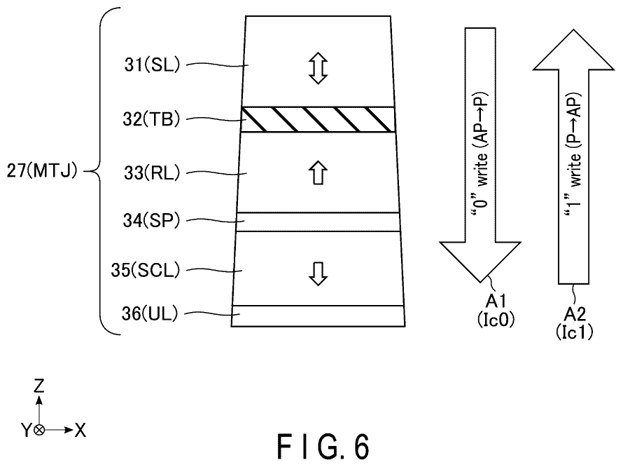

Next, an example of a cross-sectional structure of the magnetoresistive effect element MTJ of the magnetic memory device 1 according to the first embodiment, that is, the MTJ body will be described with reference to FIG. 6. FIG. 6 is a cross-sectional view illustrating an example of a cross-sectional structure of the magnetoresistive effect element MTJ included in the magnetic memory device 1 according to the first embodiment.

The MTJ body 27 used as the magnetoresistive effect element MTJ includes a ferromagnet 31, a nonmagnet 32, a ferromagnet 33, a nonmagnet 34, a ferromagnet 35, and a nonmagnet 36.

The ferromagnet 31 is a conductive film having ferromagnetism. The ferromagnet 31 has a direction of an easy axis of magnetization in a direction perpendicular to the film surface (Z direction). The ferromagnet 31 includes iron (Fe). The ferromagnet 31 may further include at least one element of cobalt (Co) and nickel (Ni). In addition, the ferromagnet 31 may further include boron (B). More specifically, for example, the ferromagnet 31 includes cobalt iron boron (CoFeB), iron boride (FeB), or cobalt boride (CoB). The ferromagnet 31 is used as a storage layer SL.

The nonmagnet 32 is provided on a lower surface of the ferromagnet 31. The nonmagnet 32 is an insulating film having nonferromagnetism. The nonmagnet 32 is used as a tunnel barrier layer TB. The nonmagnet 32 is provided between the ferromagnet 31 and the ferromagnet 33, and forms a magnetic tunnel junction together with the ferromagnet 31 and the ferromagnet 33. In addition, in a case where an initial amorphous layer such as cobalt iron boron (CoFeB) is used for an interface layer of the ferromagnet 31 and the ferromagnet 33, the nonmagnet 32 functions as a seed material that is a nucleus for growing a crystalline film from the interface with the ferromagnet 31 in the crystallization process of the ferromagnet 31.

Similarly, in a case where cobalt iron boron (CoFeB) is used as the interface layer of the ferromagnet 33, the nonmagnet 32 also functions as a seed material for the ferromagnet 33. Here, the initial amorphous layer is a layer that is in an amorphous state immediately after film formation and crystallizes after the annealing treatment. The nonmagnet 32 has a tetragonal or cubic structure in which a film surface is oriented on the (001) surface.

Examples of the oxide used for the nonmagnet 32 include magnesium oxide (MgO). Magnesium oxide (MgO) has a NaCl structure. In a case where magnesium oxide (MgO) is used for the nonmagnet 32, the (001) interface of magnesium oxide (MgO) and the (001) interface of cobalt iron boron (CoFeB) are matched with each other. Therefore, cobalt iron boron (CoFeB) is crystal-grown through the annealing treatment to form a (001)-oriented body-centered cubic structure.

The ferromagnet 33 is provided on a lower surface of the nonmagnet 32. The ferromagnet 33 is a conductive film having ferromagnetism. The ferromagnet 33 is used as a reference layer RL. The ferromagnet 33 has a direction of an easy axis of magnetization in a direction perpendicular to the film surface (Z direction). The magnetization direction of the ferromagnet 33 is fixed. In the example of FIG. 6, the magnetization direction of the ferromagnet 33 is a direction from the ferromagnet 33 toward the ferromagnet 31. Note that “the magnetization direction is fixed” means that the magnetization direction is not changed by a torque of a magnitude that can reverse the magnetization direction of the ferromagnet 31. Usually, an interface layer is used for the ferromagnet 33. For the interface layer of the ferromagnet 33, the initial amorphous layer such as cobalt iron boron (CoFeB) is used. Furthermore, an auxiliary ferromagnetic layer is provided so as to be in contact with a surface of the cobalt-iron-boron (CoFeB) layer opposite to a surface in contact with the magnesium oxide (MgO) layer. The auxiliary ferromagnetic layer includes, for example, at least one alloy film selected from cobalt platinum (CoPt), cobalt nickel (CoNi), and cobalt palladium (CoPd). The auxiliary ferromagnetic layer is a stacked film such as a stacked film including Co/Pt or a stacked film including Co/Pd.

The cobalt-iron-boron (CoFeB) layer that is the initial amorphous layer is used by being stacked with the above-described CoPt, CoPd, the stacked film including Co/Pt, the stacked film including Co/Pd, or the like. In this case, in the interface layer of the ferromagnet 33, for example, the above-described CoFeB layer, MgO that is (001)-oriented more than the other layers is formed on the nonmagnet 32 side.

The nonmagnet 34 is provided on a lower surface of the ferromagnet 33. The nonmagnet 34 is a conductive film having nonmagnetism. The nonmagnet 34 is used as a spacer layer SP. The nonmagnet 34 includes, for example, an element selected from ruthenium (Ru), osmium (Os), rhodium (Rh), iridium (Ir), vanadium (V), and chromium (Cr), or an alloy thereof. The thickness of the nonmagnet 34 is, for example, 2 nanometers (nm) or less.

The ferromagnet 35 is provided on a lower surface of the nonmagnet 34. In other words, the ferromagnet 35 is provided on the side opposite to the ferromagnet 31 with respect to the ferromagnet 33. The ferromagnet 35 is a conductive film having ferromagnetism. The ferromagnet 35 is used as a shift cancelling layer SCL. The ferromagnet 35 has a direction of an easy axis of magnetization in a direction perpendicular to the film surface (Z direction). The magnetization direction of the ferromagnet 35 is fixed. In the example of FIG. 6, the magnetization direction of the ferromagnet 35 is a direction from the ferromagnet 33 toward the ferromagnet 35. The ferromagnet 35 includes, for example, at least one alloy layer selected from cobalt platinum (CoPt), cobalt nickel (CoNi), and cobalt palladium (CoPd). In addition, the ferromagnet 35 may be a stacked film such as a stacked film including Co/Pt or a stacked film including Co/Pd.

The ferromagnet 33 and the ferromagnet 35 are antiferromagnetically coupled by the nonmagnet 34. That is, the ferromagnet 33 and the ferromagnet 35 are coupled so as to have magnetization directions antiparallel to each other. Such a coupling structure between the ferromagnet 33 and the ferromagnet 35 through the nonmagnet 34 is referred to as a synthetic anti-ferromagnetic (SAF) structure. With the synthetic anti-ferromagnetic structure, the ferromagnet 35 can cancel the influence of the stray field of the ferromagnet 33 on the change in the magnetization direction of the ferromagnet 31. Thus, the ferromagnet 35 can reduce the substantial stray field of the ferromagnet 33.

The nonmagnet 36 is provided on a lower surface of the ferromagnet 35. The nonmagnet 36 is a conductive film having nonmagnetism. The nonmagnet 36 is used as an under layer (UL). The nonmagnet 36 includes, for example, at least one element selected from zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The magnetoresistive effect element MTJ can take either a low resistance state or a high resistance state depending on whether the relative relationship between the magnetization directions of the storage layer SL and the reference layer RL is parallel or antiparallel. In the present embodiment, the magnetization direction of the storage layer SL with respect to the magnetization direction of the reference layer RL is controlled by flowing a write current through such a magnetoresistive effect element MTJ. Specifically, a write method using spin transfer torque generated by flowing the current through the magnetoresistive effect element MTJ is employed.

In a case where a write current Ic0 of a certain magnitude flows in the magnetoresistive effect element MTJ in the direction from the storage layer SL toward the reference layer RL, that is, in the direction of an arrow A1 in FIG. 6, the relative relationship between the magnetization directions of the storage layer SL and the reference layer RL becomes parallel. In this parallel state, the resistance value of the magnetoresistive effect element MTJ is the lowest, and the magnetoresistive effect element MTJ is set to the low resistance state. This low resistance state is referred to as a “P (parallel) state” and is defined as, for example, a state of data “0”.

In addition, in a case where a write current Ic1 larger than the write current Ic0 flows in the magnetoresistive effect element MTJ in the direction from the reference layer RL toward the storage layer SL, that is, in the direction of an arrow A2 in FIG. 6, the relative relationship between the magnetization directions of the storage layer SL and the reference layer RL becomes antiparallel. In this antiparallel state, the resistance value of the magnetoresistive effect element MTJ, that is, the MTJ body 27 is the highest, and the magnetoresistive effect element MTJ is set to the high resistance state.

This high resistance state is referred to as a “AP (antiparallel) state” and is defined as, for example, a state of data “1”.

Note that the definition of the data “1” and the data “0” is not limited to the above-described example. For example, the P state may be defined as data “1”, and the AP state may be defined as data “0”.

Furthermore, the MTJ body 27 is not limited to the structure in FIG. 6. The MTJ body 27 may include, for example, other layers, or each of ferromagnets and nonmagnets may include a plurality of layers.

### 1.2 Method of Manufacturing Memory Cell Array

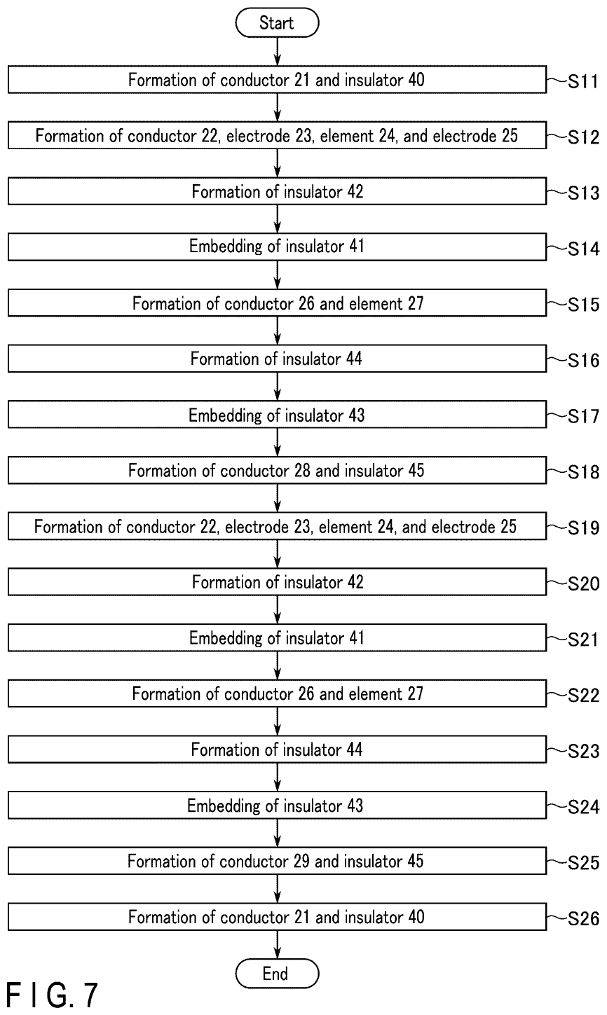

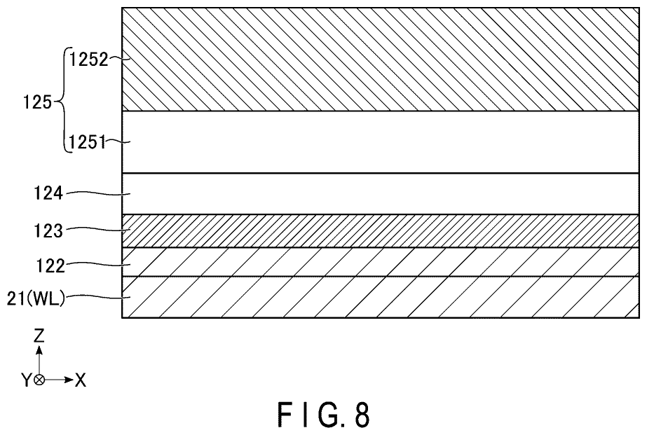

Next, a method of manufacturing the memory cell array 10 of the magnetic memory device 1 according to the first embodiment will be described. FIG. 7 is a flow chart illustrating an example of the method of manufacturing the memory cell array 10 in the magnetic memory device 1 according to the first embodiment. FIGS. 8 to 24 are cross-sectional views for explaining an example of the method of manufacturing the memory cell array 10 in the magnetic memory device 1 according to the first embodiment. FIGS. 8 to 24 are cross sections corresponding to FIG. 4.

First, in S11 of FIG. 7, the plurality of conductors 21 and the insulator 40 are formed on the upper surface of the semiconductor substrate (not illustrated) serving as a wafer WF.

Specifically, as illustrated in FIG. 8, after the conductive layer is provided on the upper surface of the semiconductor substrate, a mask having an opening at a portion excluding a region corresponding to the word line WL is formed by photolithography or the like. Then, anisotropic etching using the formed mask is performed. As a result, the conductive layer is divided, the plurality of conductors 21 arrayed along the Y direction are formed, and holes reaching the semiconductor substrate are formed. The anisotropic etching in this step is, for example, reactive ion etching (RIE). Then, the insulator 40 is embedded in the formed holes. Thus, the insulator 40 is formed.

Next, in S12 of FIG. 7, the conductor 22, the electrode 23, the selector body 24, and the electrode 25 are formed on the upper surface of each of the plurality of conductors 21.

Specifically, as illustrated in FIG. 8, a conductive layer 122, an electrode layer 123, a switching element layer (hereinafter, referred to as a selector layer) 124, and an electrode layer 125 are formed in this order on the upper surfaces of the plurality of conductors 21 and the insulator 40. In the electrode layer 125, a conductive layer 1251 and a conductive layer 1252 are formed in this order. The conductive layer 1251 is formed of at least one element or compound selected from carbon (C) and carbon nitride (CN). The conductive layer 1252 is formed of at least one element or compound selected from high melting point metal elements and compounds of high melting point metal elements.

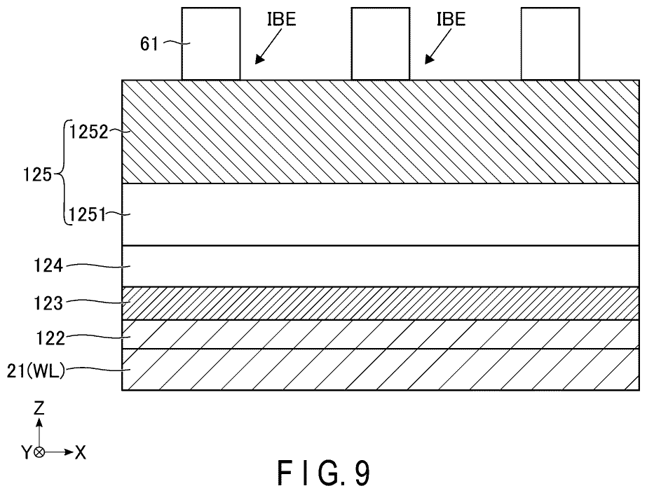

Next, as illustrated in FIG. 9, a plurality of masks 61 are formed. In the plurality of masks 61, openings are formed by photolithography or the like at potions excluding regions corresponding to the conductor 22, the electrode 23, the selector body 24, and the electrode 25 to be manufactured from the conductive layer 122, the electrode layer 123, the selector layer 124, and the electrode layer 125, respectively. The plurality of masks 61 include, for example, titanium nitride (TiN), and protect portions that function as the conductor 22, the electrode 23, the selector body 24, and the electrode 25 in ion beam etching (IBE) to be described later. The plurality of masks 61 are provided, for example, as a plurality of columnar structures arrayed in a matrix on an upper surface of the electrode layer 125, and each of the plurality of columnar structures protects a region corresponding to one memory cell MC.

Next, as illustrated in FIG. 9, the conductive layer 122, the electrode layer 123, the selector layer 124, and the electrode layer 125 are etched by ion beam etching.

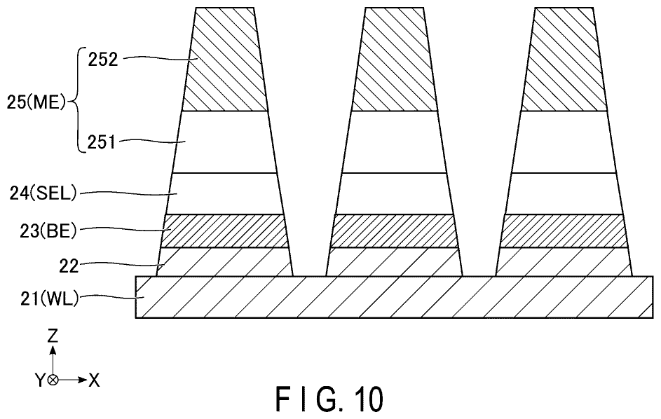

Thus, portions that are not protected by the plurality of masks 61 are removed from the conductive layer 122, the electrode layer 123, the selector layer 124, and the electrode layer 125, and the plurality of conductors 21 and the insulator 40 located below the portions are exposed. By such ion beam etching, as illustrated in FIG. 10, the plurality of conductors 22, the plurality of electrodes 23, the plurality of selector bodies 24, and the plurality of electrodes 25 are formed from the conductive layer 122, the electrode layer 123, the selector layer 124, and the electrode layer 125, respectively. That is, a structure is formed in which the conductor 22, the electrode 23, the selector body 24, and the electrode 25 are stacked. In other words, the plurality of first layer stacks each including the conductor 22, the electrode 23, the selector body 24, and the electrode 25 are formed.

Next, in S13 of FIG. 7, the insulator 42 is formed on the side surface of each of the plurality of first layer stacks.

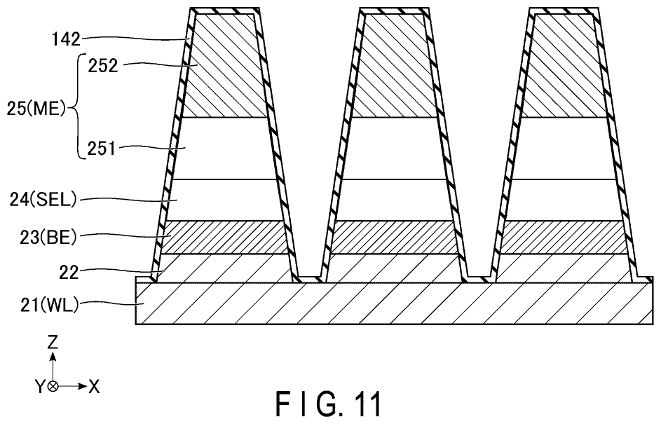

Specifically, as illustrated in FIG. 11, an insulating layer 142 is formed on the upper surface of each of the plurality of conductors 21, the upper surface of the insulator 40, an upper surface of each of the plurality of first layer stacks, and the side surface of each of the plurality of first layer stacks.

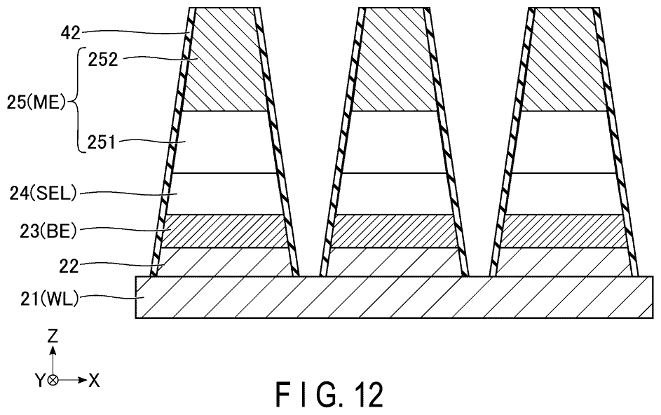

Next, as illustrated in FIG. 12, the insulating layer 142 is etched by anisotropic etching. Thus, the insulating layer 142 on the upper surface of each of the plurality of conductors 21, the insulating layer 142 on the upper surface of the insulator 40, and the insulating layer 142 on the upper surface of each of the plurality of first layer stacks are removed to form the plurality of insulators 42.

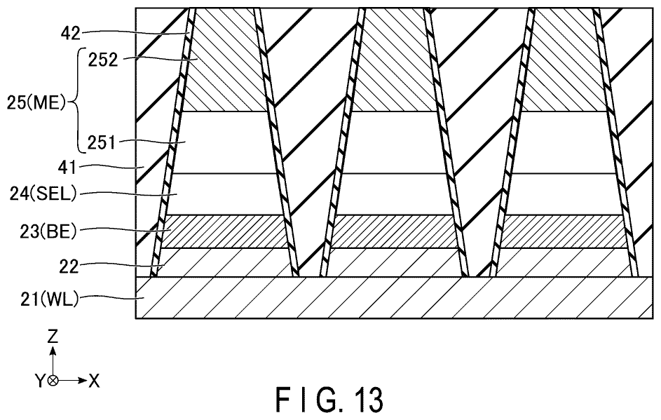

Next, in S14 of FIG. 7, as illustrated in FIG. 13, the insulator 41 is embedded in the region between two insulators 42 adjacent to each other.

Next, in S15 of FIG. 7, the conductor 26 and the MTJ body 27 are formed on the upper surface of each of the plurality of first layer stacks.

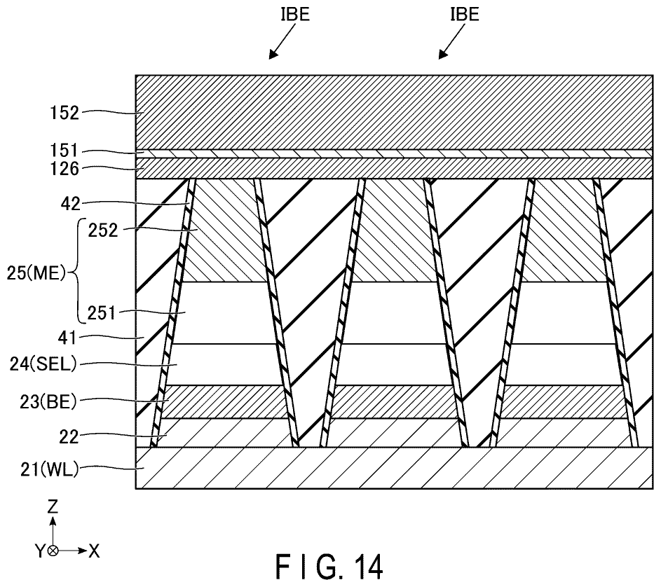

Specifically, as illustrated in FIG. 14, a conductive layer 126, a conductive layer 151, and a conductive layer 152 are formed in this order on the upper surfaces of the plurality of electrodes 25 (the plurality of first layer stacks), the insulator 41, and the plurality of insulators 42. The conductive layer 126 includes, for example, hafnium (Hf), hafnium boride (HfB), or the like. The thickness of the conductive layer 126 is, for example, about 3 nanometers (nm).

The thickness of the conductive layer 151 is, for example, about 0.5 nanometers (nm).

The conductive layer 152 includes, for example, hafnium (Hf), hafnium boride (HfB), or the like. The thickness of the conductive layer 152 is, for example, about 10 nanometers (nm).

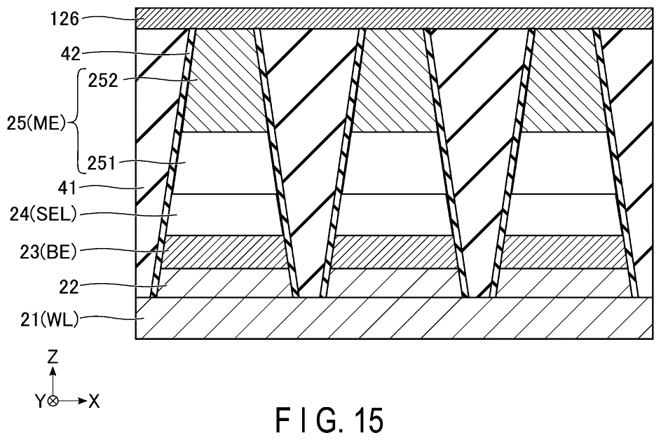

Next, as illustrated in FIG. 14, the conductive layers 151 and 152 are etched by ion beam etching. Thus, the conductive layer 151 and the conductive layer 152 are removed, and the conductive layer 126 is exposed. By such ion beam etching, an upper surface of the conductive layer 126 is flattened as illustrated in FIG. 15. The thickness of the conductive layer 126 after the flattening is, for example, about 3 nanometers (nm). For example, the ion beam etching is controlled by detecting an optical emission spectroscopy (OES) signal of the conductive layer 151 to detect an end point of the ion beam etching in the process of the etching.

Note that the upper surface of the conductive layer 126 may be flattened by chemical mechanical polishing (CMP), RIE, or the like.

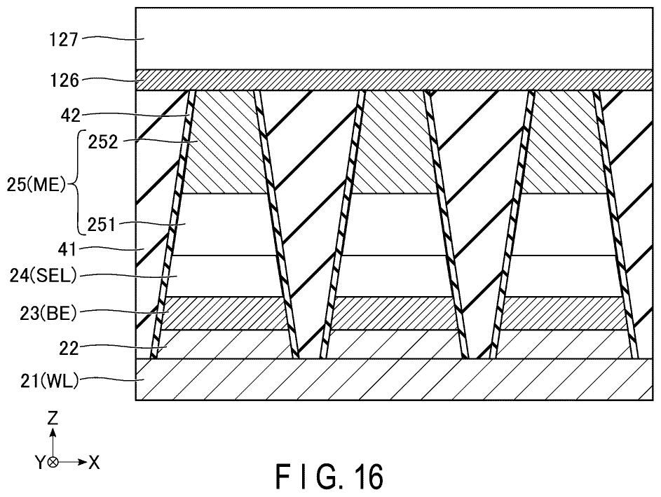

Next, as illustrated in FIG. 16, a magnetoresistive effect element layer 127 is formed on the upper surface of the conductive layer 126. The magnetoresistive effect element layer 127 is a layer stack in which each layer included in the magnetoresistive effect element MTJ described in FIG. 6 is formed in a flat plate shape in the described stacking order.

Next, to enhance the crystallinity of the magnetoresistive effect element layer 127, the annealing treatment is performed on the magnetoresistive effect element layer 127. The annealing treatment is performed, for example, at 300° C. to 400° C. for an arbitrary time.

Thus, each layer of the magnetoresistive effect element layer 127 is crystallized.

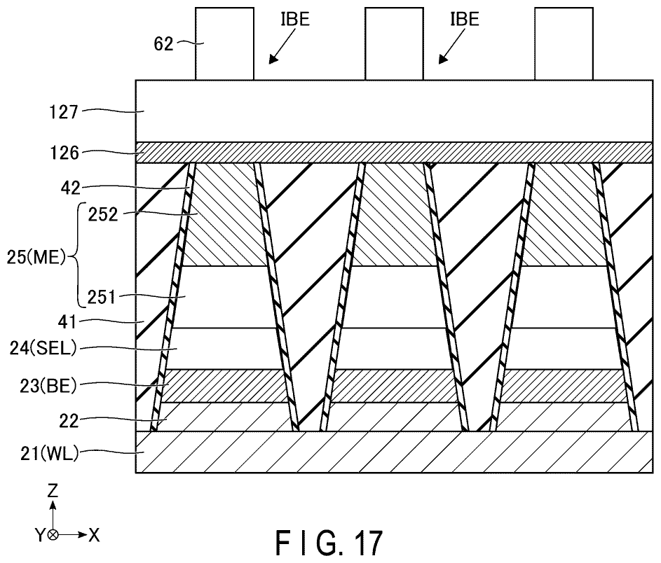

Next, as illustrated in FIG. 17, a plurality of masks 62 are formed. In the plurality of masks 62, openings are formed by photolithography or the like at potions excluding regions corresponding to the conductor 26 and the MTJ body 27 to be manufactured from the conductive layer 126 and the magnetoresistive effect element layer 127, respectively. The plurality of masks 62 include, for example, titanium nitride, and protect portions that function as the conductor 26 and the MTJ body 27 in ion beam etching to be described later. The plurality of masks 62 are provided, for example, as a plurality of columnar structures arrayed in a matrix on an upper surface of the magnetoresistive effect element layer 127, and each of the plurality of columnar structures protects a region corresponding to one memory cell MC.

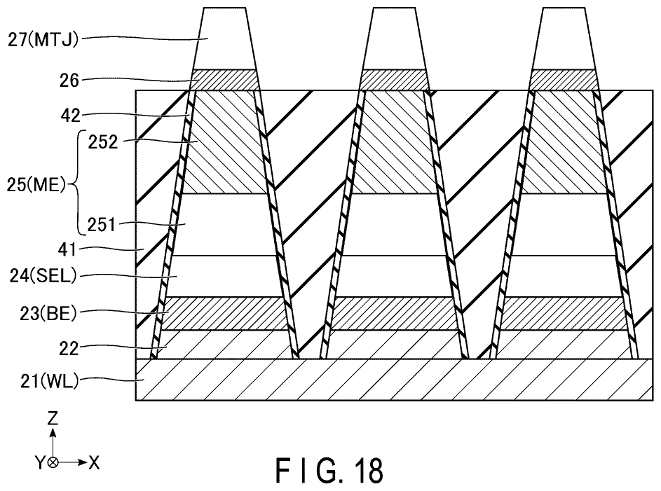

Next, as illustrated in FIG. 17, the conductive layer 126 and the magnetoresistive effect element layer 127 are etched by ion beam etching. Thus, portions that are not protected by the plurality of masks 62 are removed from the conductive layer 126 and the magnetoresistive effect element layer 127, and the insulator 41 located below the portions is exposed. By such ion beam etching, as illustrated in FIG. 18, the plurality of conductors 26 and the plurality of MTJ bodies 27 are formed from the conductive layer 126 and the magnetoresistive effect element layer 127. That is, the plurality of second layer stacks each including the conductor 26 and the MTJ body 27 are formed.

Next, in S16 of FIG. 7, the insulator 44 is formed on the side surface of each of the plurality of second layer stacks.

Specifically, after an insulating layer is formed on an upper surface of the insulator 41, an upper surface of each of the plurality of second layer stacks, and the side surface of each of the plurality of second layer stacks, the insulating layer is etched by anisotropic etching.

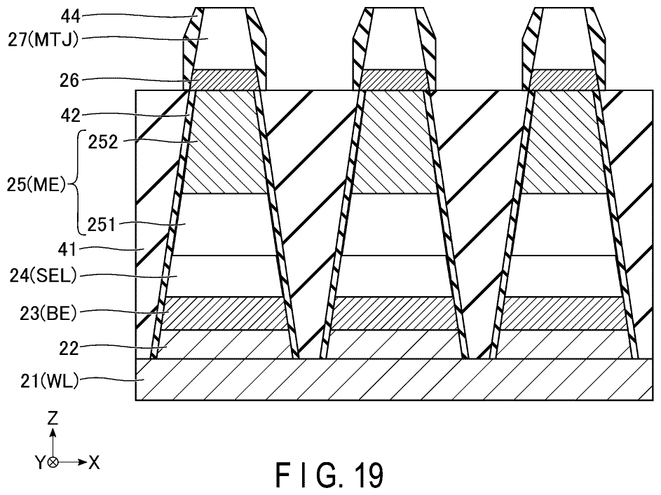

Thus, as illustrated in FIG. 19, the insulating layer on the upper surface of the insulator 41 and the insulating layer on the upper surface of each of the plurality of second layer stacks are removed, and the plurality of insulators 44 are formed.

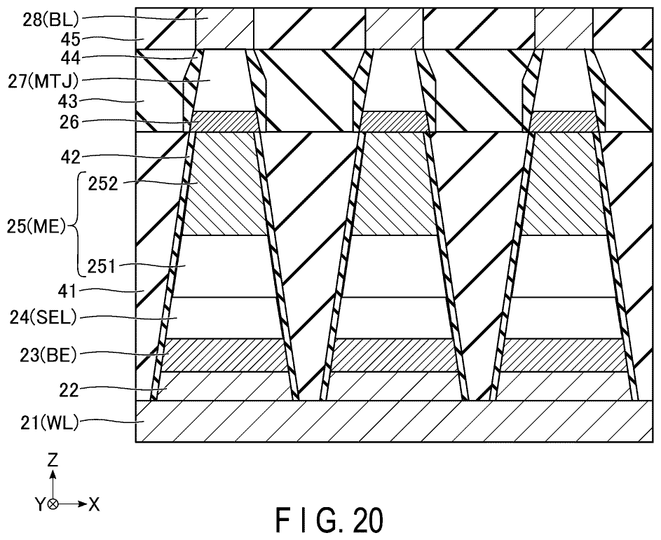

Next, in S17 of FIG. 7, as illustrated in FIG. 20, the insulator 43 is embedded in the region between two insulators 44 adjacent to each other.

Next, in S18 of FIG. 7, the plurality of conductors 28 and the insulator 45 are formed on the upper surfaces of the plurality of second layer stacks, the insulator 43, and the plurality of insulators 44.

Specifically, as illustrated in FIG. 20, after the conductive layer is provided on the upper surfaces of the plurality of second layer stacks, the insulator 43, and the plurality of insulators 44, a mask having an opening at a portion excluding a region corresponding to the bit line BL is formed by photolithography or the like. Then, anisotropic etching using the formed mask is performed. As a result, the conductive layer is divided, the plurality of conductors 28 arrayed along the X direction are formed, and holes reaching the insulator 43 are formed. The anisotropic etching in this step is, for example, RIE. Then, the insulator 45 is embedded in the formed holes.

S11 to S18 of FIG. 7 are performed as described above, thereby forming the first-stage stacked structure.

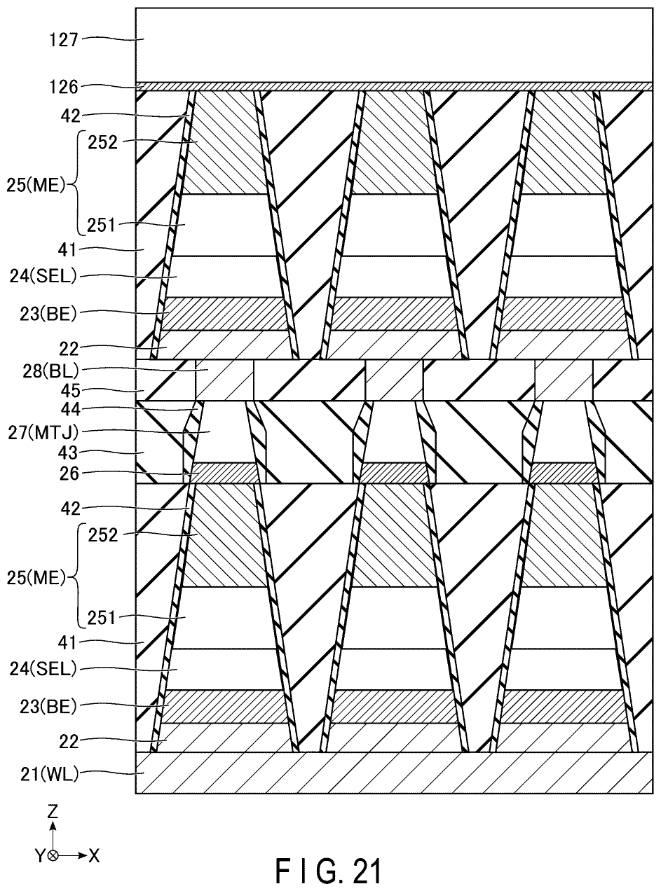

Next, in S19 of FIG. 7, as illustrated in FIG. 21, the conductor 22, the electrode 23, the selector body 24, and the electrode 25 are formed on the upper surface of each of the plurality of conductors 28, as in the formation of the first-stage stacked structure. That is, the structure is formed in which the conductor 22, the electrode 23, the selector body 24, and the electrode 25 are stacked. In other words, the plurality of first layer stacks each including the conductor 22, the electrode 23, the selector body 24, and the electrode 25 are formed.

Next, in S20 of FIG. 7, as illustrated in FIG. 21, the insulator 42 is formed on the side surface of each of the plurality of first layer stacks, as in the formation of the first-stage stacked structure.

Next, in S21 of FIG. 7, as illustrated in FIG. 21, the insulator 41 is embedded in the region between two insulators 42 adjacent to each other, as in the formation of the first-stage stacked structure.

Next, in S22 of FIG. 7, the conductor 26 and the MTJ body 27 are formed on the upper surface of each of the plurality of first layer stacks.

Specifically, as illustrated in FIG. 21, the conductive layer 126 is formed on the upper surfaces of the plurality of electrodes 25 (the plurality of first layer stacks), the insulator 41, and the plurality of insulators 42. The conductive layer 126 includes, for example, hafnium (Hf), hafnium boride (HfB), or the like. The thickness of the conductive layer 126 is, for example, about 1 nanometer (nm). The magnetoresistive effect element layer 127 is formed on the upper surface of the conductive layer 126. Note that the upper surface of the conductive layer 126 may be flattened as in S15 of FIG. 7. In this case, the upper surface of each layer included in the magnetoresistive effect element layer 127 provided on the upper surface of the conductive layer 126 is also flattened. Therefore, the characteristics of the magnetoresistive effect element layer 127 are improved.

Next, to enhance the crystallinity of the magnetoresistive effect element layer 127, the annealing treatment is performed on the magnetoresistive effect element layer 127, as in the formation of the first-stage stacked structure. The annealing treatment is performed, for example, at 300° C. to 400° C. for an arbitrary time.

Thus, each layer of the magnetoresistive effect element layer 127 is crystallized. Note that the temperature and time for the annealing treatment may be different between a process of forming the first-stage stacked structure and a process of forming the second-stage stacked structure.

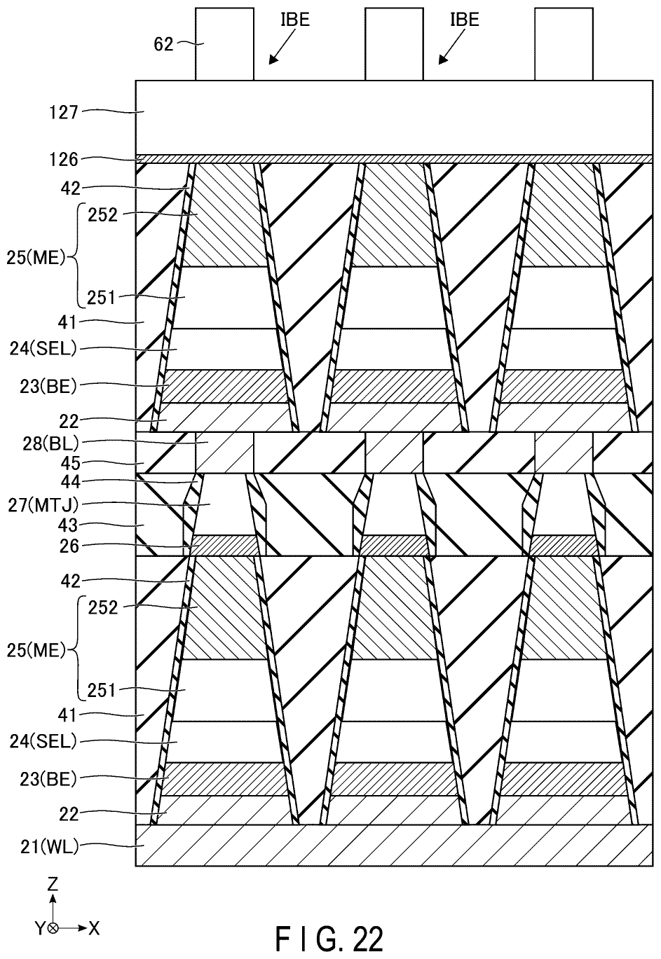

Next, as illustrated in FIG. 22, the plurality of masks 62 are formed as in the formation of the first-stage stacked structure.

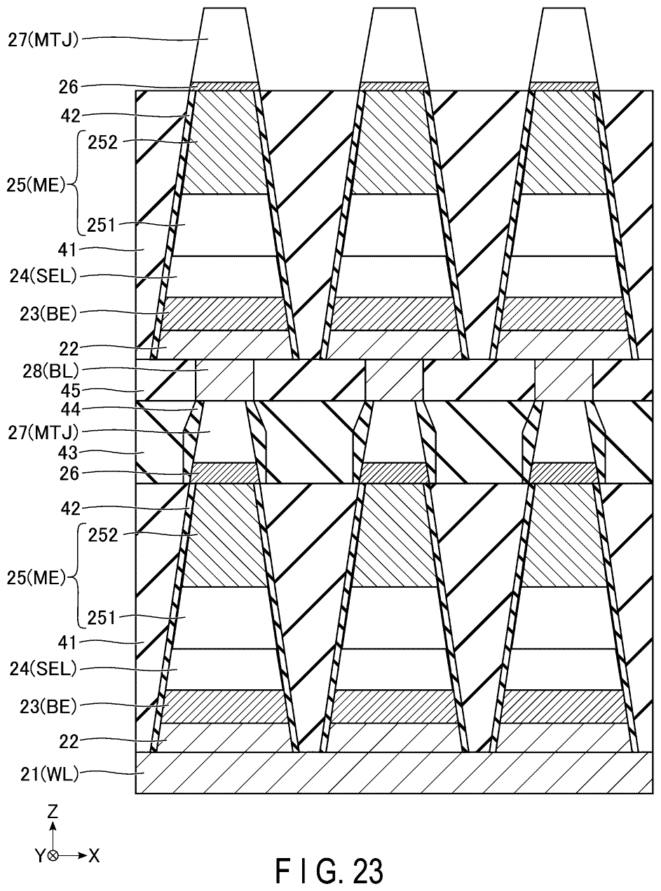

Next, as illustrated in FIG. 22, the conductive layer 126 and the magnetoresistive effect element layer 127 are etched by ion beam etching, as in the formation of the first-stage stacked structure. Thus, as illustrated in FIG. 23, the plurality of conductors 26 and the plurality of MTJ bodies 27 are formed from the conductive layer 126 and the magnetoresistive effect element layer 127. That is, the plurality of second layer stacks each including the conductor 26 and the MTJ body 27 are formed.

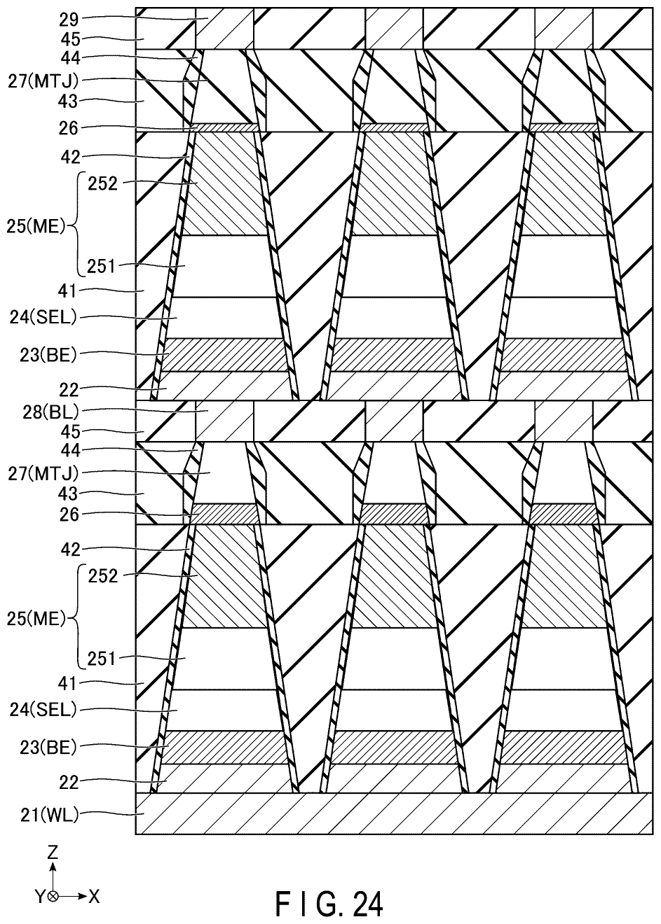

Next, in S23 of FIG. 7, as illustrated in FIG. 24, the insulator 44 is formed on the side surface of each of the plurality of second layer stacks, as in the formation of the first-stage stacked structure.

Next, in S24 of FIG. 7, as illustrated in FIG. 24, the insulator 43 is embedded in the region between two insulators 44 adjacent to each other, as in the formation of the first-stage stacked structure.

Next, in S25 of FIG. 7, the plurality of conductors 29 and the insulator 45 are formed on the upper surfaces of the plurality of second layer stacks, the insulator 43, and the plurality of insulators 44.

Specifically, after the conductive layer is provided on the upper surfaces of the plurality of second layer stacks, the insulator 43, and the plurality of insulators 44, a mask having an opening at a portion excluding a region corresponding to the conductor 29 is formed by photolithography or the like. Then, anisotropic etching using the formed mask is performed. As a result, as illustrated in FIG. 24, the conductive layer is divided, the plurality of conductors 29 are formed, and holes reaching the insulator 43 are formed. The anisotropic etching in this step is, for example, RIE. Then, the insulator 45 is embedded in the formed holes, as illustrated in FIG. 24.

Next, in S26 of FIG. 7, as illustrated in FIG. 4, the plurality of conductors 21 and the insulator 40 are formed on the upper surfaces of the plurality of conductors 29 and the insulator 45, as in the formation of the first-stage stacked structure.

S19 to S26 of FIG. 7 are performed as described above, thereby forming the second-stage stacked structure. As described above, a configuration corresponding to the memory cell array 10 is formed on the wafer WF. Then, the wafer WF is diced into chips and the magnetic memory device 1 is formed.

The magnetic memory device 1 is formed by the above-described manufacturing process. Note that the above-described manufacturing process is merely an example, and the manufacturing process of the magnetic memory device 1 is not limited thereto. For example, other processing may be inserted between the manufacturing steps, or some processing may be omitted or integrated. In addition, the manufacturing steps may be shuffled within the possible range.

### 1.3 Effects According to Present Embodiment

According to the magnetic memory device 1 according to the first embodiment, it is possible to suppress the deterioration of the characteristics of the magnetoresistive effect element. Hereinafter, detailed of the effect of the magnetic memory device 1 according to the first embodiment will be described.

In a magnetic memory device having a structure in which the memory cells MC including the magnetoresistive effect elements MTJ are multilayered, that is, having the first-stage stacked structure and the second-stage stacked structure, the annealing treatment is performed in the process of forming the first-stage stacked structure, and the annealing treatment is performed in the process of forming the second-stage stacked structure. That is, the annealing treatment is performed twice. Thus, the magnetoresistive effect element MTJ included in the first-stage stacked structure is heated twice in total at two annealing treatments. The magnetoresistive effect element MTJ included in the second-stage stacked structure is heated once at one annealing treatment. For this reason, the characteristics of the magnetoresistive effect element MTJ included in the first-stage stacked structure may be deteriorated more than those of the magnetoresistive effect element MTJ included in the second-stage stacked structure.

Therefore, in the present embodiment, the conductive layer 126 is formed on the upper surface of the electrode 25 and the upper surface of the conductive layer 126 is flattened in the process of forming the first-stage stacked structure. The magnetoresistive effect element layer 127 is formed on the upper surface of the flattened conductive layer 126. Thus, the upper surface of each layer included in the magnetoresistive effect element layer 127 provided on the upper surface of the conductive layer 126 is also flattened. Therefore, the characteristics of the magnetoresistive effect element layer 127 are improved. That is, the characteristics of the MTJ body 27 included in the formed first-stage stacked structure are improved. As a result, even if the annealing treatment is performed twice and the characteristics of the MTJ body 27 included in the first-stage stacked structure are deteriorated, it is possible to suppress the characteristics of the MTJ body 27 included in the first-stage stacked structure from being deteriorated more than the characteristics of the MTJ body 27 included in the second-stage stacked structure. That is, according to the present embodiment, it is possible to suppress the deterioration of the characteristics of the magnetoresistive effect element.

For example, the thickness of the conductor 26 included in the first-stage stacked structure is set to such a thickness that the characteristics of the MTJ body 27 included in the first-stage stacked structure are substantially equivalent to the characteristics of the MTJ body 27 included in the second-stage stacked structure after the annealing treatment is performed twice. As a result, the MTJ body 27 included in the first-stage stacked structure can have substantially the same characteristics as the MTJ body 27 included in the second-stage stacked structure.

In addition, the conductive layer 126 is provided between the magnetoresistive effect element layer 127 and the electrode 25. Due to this, the crystallinity of each layer included in the magnetoresistive effect element layer 127 is not affected by the crystallinity of the electrode 25. Therefore, the crystallinity of the magnetoresistive effect element layer 127 is improved.

### 2. Second Embodiment

A magnetic memory device according to a second embodiment will be described. A magnetic memory device 1A according to the second embodiment has a different cross-sectional structure of a memory cell array 10A and a different method of manufacturing the memory cell array 10A from those of the first embodiment. Hereinafter, the differences from the first embodiment will be described.

### 2.1 Cross-sectional Structure of Memory Cell Array

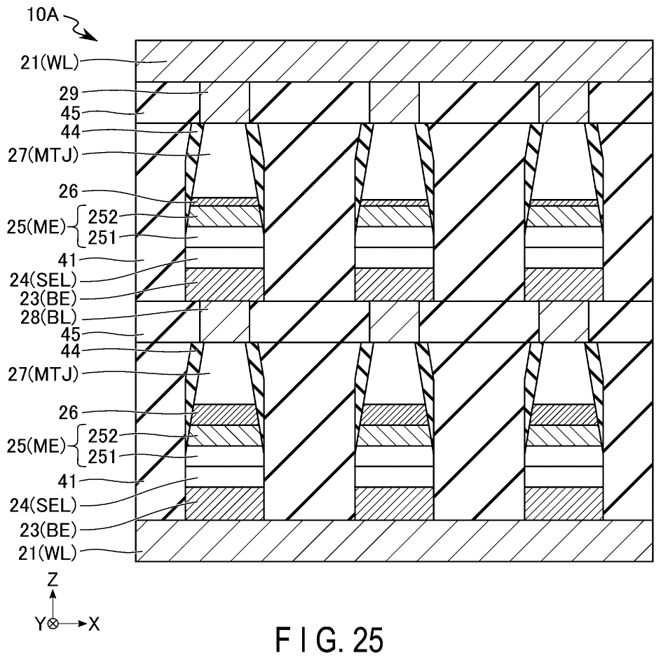

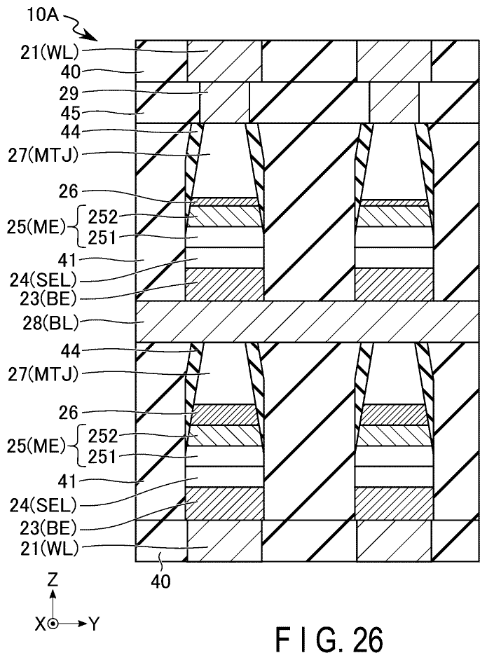

An example of the cross-sectional structure of the memory cell array 10A will be described with reference to FIGS. 25 and 26. FIG. 25 is a cross-sectional view taken along line IV-IV in FIG. 3 that is illustrated in the first embodiment, illustrating an example of the cross-sectional structure of the memory cell array 10A included in the magnetic memory device 1A according to the second embodiment. FIG. 26 is a cross-sectional view taken along line V-V in FIG. 3 that is illustrated in the first embodiment, illustrating an example of the cross-sectional structure of the memory cell array 10A included in the magnetic memory device 1A according to the second embodiment.

As illustrated in FIGS. 25 and 26, the memory cell array 10A includes a plurality of conductors 21, a plurality of electrodes 23, a plurality of selector bodies 24, a plurality of electrodes 25, a plurality of conductors 26, a plurality of MTJ bodies 27, a plurality of conductors 28, a plurality of conductors 29, an insulator 40, an insulator 41, a plurality of insulators 44, and an insulator 45.

For example, the plurality of conductors 21 are provided above a semiconductor substrate (not illustrated). The plurality of conductors 21 are arrayed along the Y direction. Each of the plurality of conductors 21 extends along the X direction. Each of the plurality of conductors 21 has conductivity and functions as a word line WL.

The insulator 40 is provided in a region between two conductors 21 adjacent to each other in the Y direction. Due to this, each of the plurality of conductors 21 is insulated from each other in the Y direction. For the insulator 40, the same material as that of the first embodiment is used.

Note that the plurality of conductors 21 and the insulator 40 may be provided on an upper surface of the semiconductor substrate, or may be provided so as to be separated from the semiconductor substrate without being in contact with the semiconductor substrate.

The plurality of electrodes 23 are provided on an upper surface of each of the plurality of conductors 21.

The plurality of electrodes 23 provided on the upper surface of the same conductor 21 are arrayed in the X direction. Each of the plurality of electrodes 23 has conductivity and functions as a bottom electrode BE.

One corresponding selector body 24 among the plurality of selector bodies 24 is provided on an upper surface of each of the plurality of electrodes 23. Each of the plurality of selector bodies 24 functions as a switching element SEL.

One corresponding electrode 25 among the plurality of electrodes 25 is provided on an upper surface of each of the plurality of selector bodies 24. Each of the plurality of electrodes 25 has the same structure as that of the first embodiment. For conductors 251 and 252 included in the electrode 25, the same material as that of the first embodiment is used. Each of the plurality of electrodes 25 functions as a middle electrode ME.

One corresponding conductor 26 among the plurality of conductors 26 is provided on the upper surface of each of the plurality of electrodes 25. Each of the plurality of conductors 26 has conductivity and functions as a buffer layer BF. The conductor 26 includes, for example, hafnium (Hf), hafnium boride (HfB), or the like. In addition, an upper surface of the conductor 26 is flattened. The thickness of the conductor 26 is, for example, about 3 nanometers (nm).

One corresponding MTJ body 27 among the plurality of MTJ bodies 27 is provided on the upper surface of each of the plurality of conductors 26. Each of the plurality of MTJ bodies 27 has the same structure as that in FIG. 6 illustrated in the first embodiment. For a ferromagnet 31, a nonmagnet 32, a ferromagnet 33, a nonmagnet 34, a ferromagnet 35, and a nonmagnet 36 included in the MTJ body 27, the same materials as those in the first embodiment are used. Each of the plurality of MTJ bodies 27 functions as a magnetoresistive effect element MTJ.

Hereinafter, a structure including the electrode 25, the conductor 26, and the MTJ body 27 is referred to as a “third layer stack”. The memory cell array 10A includes a plurality of third layer stacks. The insulator 44 (side wall) is provided on side surface of each of the plurality of third layer stacks so as to cover a part of a side surface of the conductor 251, and side surfaces of the conductor 252, the conductor 26, and the MTJ body 27. That is, the insulator 44 covers the side surface of the electrode 25, the side surface of the conductor 26, and the side surface of the MTJ body 27. The insulator 44 is provided, for example, from a position above the upper surface of the selector body 24 to a position equivalent to an upper surface of the MTJ body 27. Due to this, each of the plurality of conductors 252 is insulated from each other. Each of the plurality of conductors 26 is insulated from each other. Each of the plurality of MTJ bodies 27 is insulated from each other. For the insulator 44, the same material as that of the first embodiment is used.

The insulator 41 is provided in a region between two adjacent electrodes 23, a region between two adjacent selector bodies 24, a region between two adjacent conductors 251, and a region between two adjacent insulators 44. Due to this, each of the plurality of electrodes 23 is insulated from each other in the Y direction. Each of the plurality of selector bodies 24 is insulated from each other. Each of the plurality of conductors 251 is insulated from each other by the insulators 41 and 44. For the insulator 41, the same material as that of the first embodiment is used.

One conductor 28 extending in the Y direction is provided so as to be in contact with the upper surface of each of the plurality of MTJ bodies 27 arrayed in the Y direction. The plurality of conductors 28 are arrayed in the X direction. Each of the plurality of conductors 28 extends along the Y direction. Each of the plurality of conductors 28 has conductivity and functions as the bit line BL.

The insulator 45 is provided in a region between two conductors 28 adjacent to each other in the X direction.

Due to this, each of the plurality of conductors 28 is insulated from each other in the X direction. For the insulator 45, the same material as that of the first embodiment is used.

A structure in which the conductor 21, the electrode 23, the selector body 24, the electrode 25, the conductor 26, the MTJ body 27, and the conductor 28 are stacked in this order as described above corresponds to a first-stage stacked structure. The memory cell MC of the first-stage stacked structure includes the electrode 23, the selector body 24, the electrode 25, the conductor 26, and the MTJ body 27. The electrode 25 is provided between the selector body 24 and the conductor 26.

The plurality of electrodes 23 are provided on an upper surface of each of the plurality of conductors 28. The plurality of electrodes 23 provided on the upper surface of the same conductor 28 are arrayed in the Y direction.

The selector body 24, the electrode 25, the conductor 26, and the MTJ body 27 are provided on the upper surface of each of the plurality of electrodes 23, as in the first-stage stacked structure. The structure of the electrode 25 is the same as that of the first-stage stacked structure. The conductor 26 includes, for example, hafnium (Hf), hafnium boride (HfB), or the like. The thickness of the conductor 26 is, for example, about 1 nanometer (nm). The structure of the MTJ body 27 is the same as that of the first-stage stacked structure. The insulator 44 is provided on the side surface of each of the plurality of third layer stacks each including the electrode 25, the conductor 26, and the MTJ body 27, as in the first-stage stacked structure. That is, the insulator 44 covers the side surface of the electrode 25, the side surface of the conductor 26, and the side surface of the MTJ body 27. The insulator 41 is provided in the region between two adjacent electrodes 23, the region between two adjacent selector bodies 24, the region between two adjacent conductors 251, and the region between two adjacent insulators 44, as in the first-stage stacked structure.

One corresponding conductor 29 among the plurality of conductors 29 is provided on the upper surface of each of the plurality of MTJ bodies 27. The plurality of conductors 29 are arrayed in the X direction and the Y direction. The insulator 45 is provided in a region between two conductors 29 adjacent to each other. Due to this, each of the plurality of conductors 29 is insulated from each other.

One conductor 21 extending in the X direction is provided so as to be in contact with an upper surface of each of the plurality of conductors 29 arrayed in the X direction. The plurality of conductors 21 are arrayed in the Y direction. Each of the plurality of conductors 21 extends along the X direction. Each of the plurality of conductors 21 has conductivity and functions as the word line WL. One conductor 21 and the plurality of conductors 29 provided on a lower surface of the conductor 21 are also collectively referred to as the word line WL.

The insulator 40 is provided in the region between two conductors 21 adjacent to each other in the Y direction, as in the first-stage stacked structure.

A structure in which the conductor 28, the electrode 23, the selector body 24, the electrode 25, the conductor 26, the MTJ body 27, the conductor 29, and the conductor 21 are stacked in this order as described above corresponds to a second-stage stacked structure. The memory cell MC of the second-stage stacked structure includes the electrode 23, the selector body 24, the electrode 25, the conductor 26, the MTJ body 27, and the conductor 29. The electrode 25 is provided between the selector body 24 and the conductor 26.

### 2.2 Method of Manufacturing Memory Cell Array

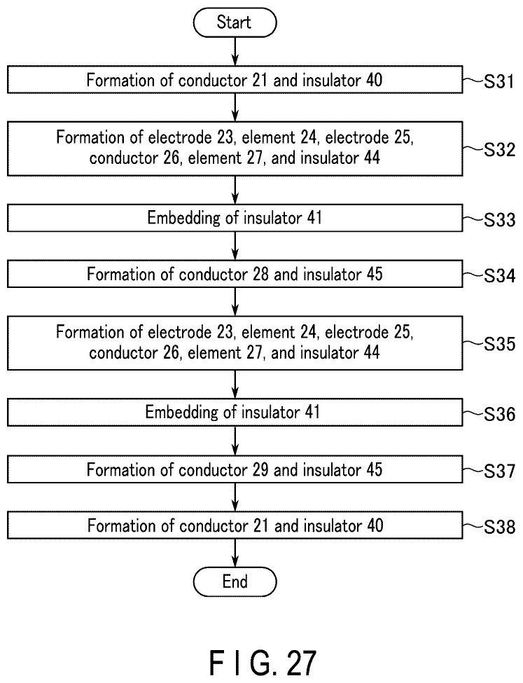

Next, a method of manufacturing the memory cell array 10A of the magnetic memory device 1A according to the second embodiment will be described. FIG. 27 is a flow chart illustrating an example of the method of manufacturing the memory cell array 10A in the magnetic memory device 1A according to the second embodiment.

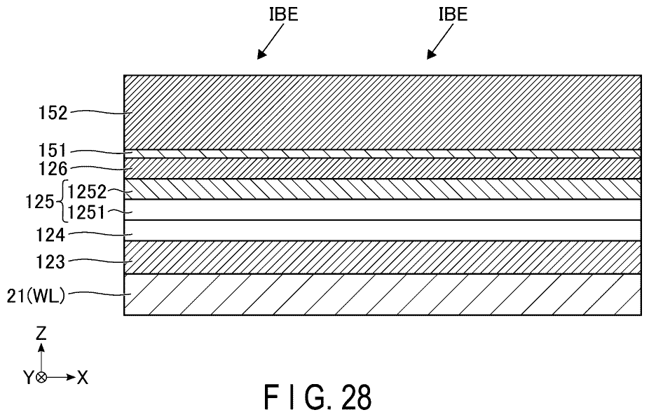

FIGS. 28 to 40 are cross-sectional views for explaining an example of the method of manufacturing the memory cell array 10A in the magnetic memory device 1A according to the second embodiment. FIGS. 28 to 40 are cross sections corresponding to FIG. 25.

First, in S31 of FIG. 27, as illustrated in FIG. 28, the plurality of conductors 21 and the insulator 40 are formed on the upper surface of the semiconductor substrate (not illustrated) serving as a wafer WF, as in the first embodiment.

Next, in S32 of FIG. 27, the electrode 23, the selector body 24, the electrode 25, the conductor 26, the MTJ body 27, and the insulator 44 are formed on the upper surface of each of the plurality of conductors 21.

Specifically, as illustrated in FIG. 28, an electrode layer 123, a selector layer 124, an electrode layer 125, a conductive layer 126, a conductive layer 151, and a conductive layer 152 are formed in this order on the upper surfaces of the plurality of conductors 21 and the insulator 40.

In the electrode layer 125, a conductive layer 1251 and a conductive layer 1252 are formed in this order.

The conductive layer 126 includes, for example, hafnium (Hf), hafnium boride (HfB), or the like. The thickness of the conductive layer 126 is, for example, about 3 nanometers (nm).

The thickness of the conductive layer 151 is, for example, about 0.5 nanometers (nm).

The conductive layer 152 includes, for example, hafnium (Hf), hafnium boride (HfB), or the like. The thickness of the conductive layer 152 is, for example, about 10 nanometers (nm).

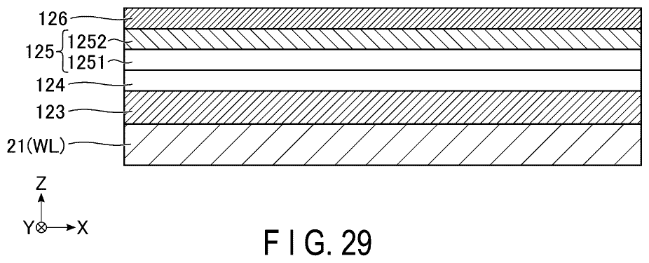

Next, the conductive layers 151 and 152 are etched by ion beam etching as in the first embodiment. Thus, the conductive layer 151 and the conductive layer 152 are removed, and the conductive layer 126 is exposed. By such ion beam etching, an upper surface of the conductive layer 126 is flattened as illustrated in FIG. 29. The thickness of the conductive layer 126 after the flattening is, for example, about 3 nanometers (nm).

Note that the upper surface of the conductive layer 126 may be flattened by CMP, RIE, or the like.

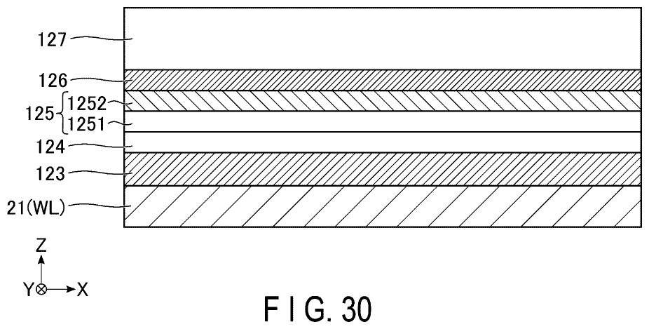

Next, as illustrated in FIG. 30, a magnetoresistive effect element layer 127 is formed on the upper surface of the conductive layer 126 as in the first embodiment. The magnetoresistive effect element layer 127 is a layer stack in which each layer included in the magnetoresistive effect element MTJ described in FIG. 6 is formed in a flat plate shape in the described stacking order.

Next, the annealing treatment is performed on the magnetoresistive effect element layer 127 as in the first embodiment. The annealing treatment is performed, for example, at 300° C. to 400° C. for an arbitrary time. Thus, each layer of the magnetoresistive effect element layer 127 is crystallized.

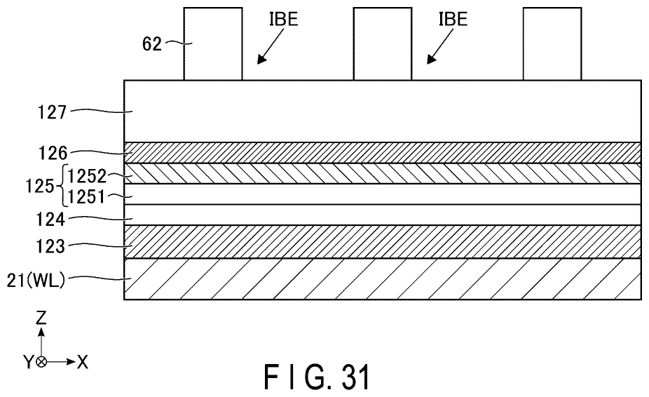

Next, as illustrated in FIG. 31, a plurality of masks 62 are formed as in the first embodiment.

Next, as illustrated in FIG. 31, the conductive layer 1251, the conductive layer 1252, the conductive layer 126, and the magnetoresistive effect element layer 127 are etched by ion beam etching. Etching is performed up to a position between an upper surface of the selector layer 124 and a lower surface of the conductive layer 1252.

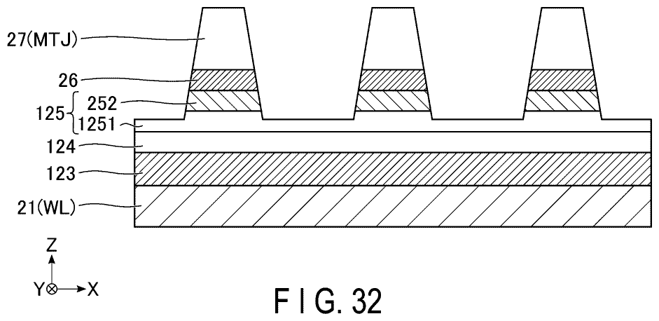

Thus, portions that are not protected by the plurality of masks 62 are removed from the conductive layer 1251, the conductive layer 1252, the conductive layer 126, and the magnetoresistive effect element layer 127, a part of an upper end of the conductive layer 1251 is removed, and the conductive layer 1251 is exposed. By such ion beam etching, as illustrated in FIG. 32, the plurality of conductors 252, the plurality of conductors 26, and the plurality of MTJ bodies 27 are formed from the conductive layer 1252, the conductive layer 126, and the magnetoresistive effect element layer 127.

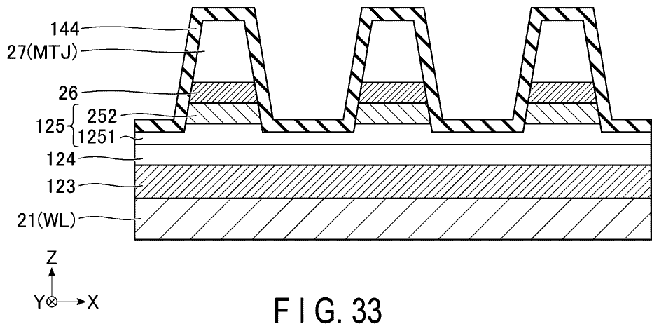

Next, as illustrated in FIG. 33, an insulating layer 144 is formed on an upper surface of the conductive layer 1251, an upper surface of each of the plurality of MTJ bodies 27, and the side surface of each of the plurality of conductors 252, the plurality of conductors 26, and the plurality of MTJ bodies 27.

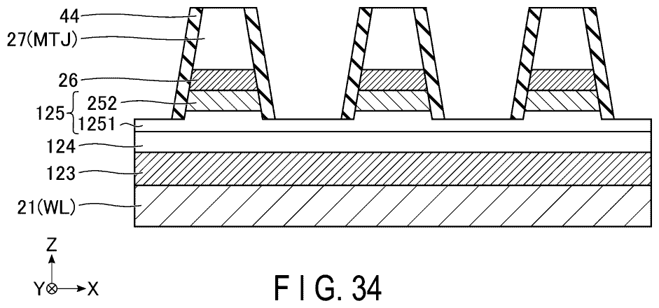

Next, as illustrated in FIG. 34, the insulating layer 144 is etched by anisotropic etching. Thus, the insulating layer 144 on the upper surface of the conductive layer 1251 and the insulating layer 144 on the upper surface of each of the plurality of MTJ bodies 27 are removed, and the plurality of insulators 44 are formed.

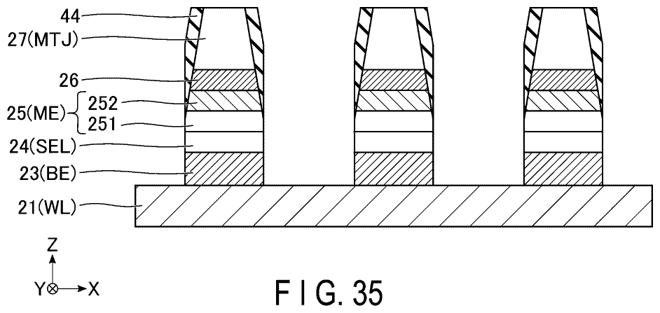

Next, portions that are not protected by the insulator 44 are removed by anisotropic etching from the electrode layer 123, the selector layer 124, and the conductive layer 1251, and the plurality of conductors 21 and the insulator 40 located below the portions are exposed. Thus, as illustrated in FIG. 35, the plurality of electrodes 23, the plurality of selector bodies 24, and the plurality of conductors 251 are formed. That is, the plurality of third layer stacks each including the electrode 25, the conductor 26 and the MTJ body 27 are formed. The anisotropic etching in this step is, for example, RIE.

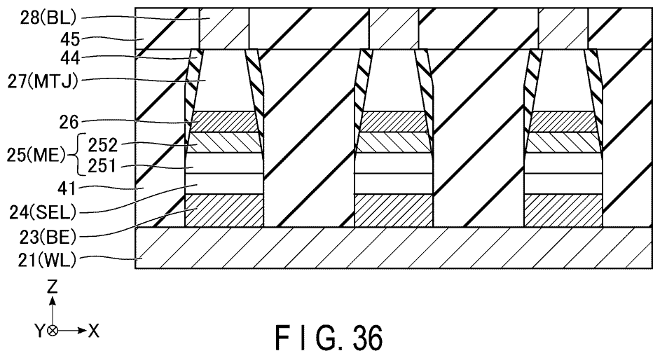

Next, in S33 of FIG. 27, as illustrated in FIG. 36, the insulator 41 is embedded in the region between two adjacent electrodes 23, the region between two adjacent selector bodies 24, the region between two adjacent conductors 251, and the region between two adjacent insulators 44.

Next, in S34 of FIG. 27, as illustrated in FIG. 36, the plurality of conductors 28 and the insulator 45 are formed on upper surfaces of the plurality of third layer stacks, the insulator 41, and the plurality of insulators 44, as in the first embodiment.

S31 to S34 of FIG. 27 are performed as described above, thereby forming the first-stage stacked structure. Next, in S35 of FIG. 27, the electrode 23, the selector body 24, the electrode 25, the conductor 26, the MTJ body 27, and the insulator 44 are formed on the upper surface of each of the plurality of conductors 28.

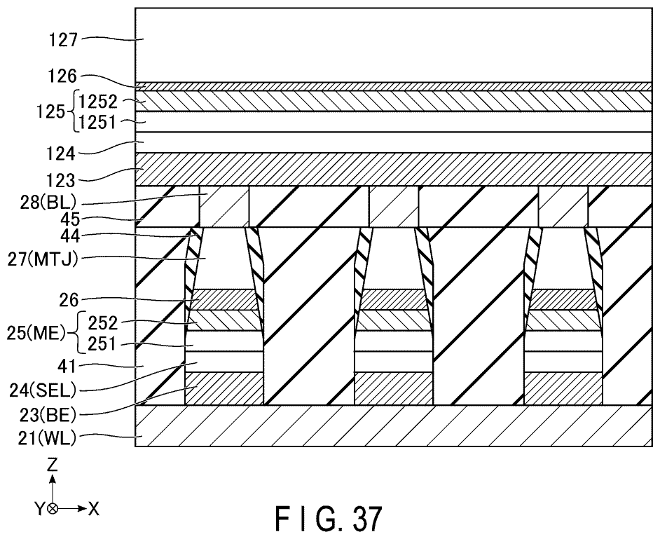

Specifically, as illustrated in FIG. 37, the electrode layer 123, the selector layer 124, and the electrode layer 125 are formed in this order on the upper surfaces of the plurality of conductors 28 and the insulator 45, as in the formation of the first-stage stacked structure. In the electrode layer 125, the conductive layer 1251 and the conductive layer 1252 are formed in this order.

Next, as illustrated in FIG. 37, the conductive layer 126 is formed on an upper surface of the electrode layer 125. The conductive layer 126 includes, for example, hafnium (Hf), hafnium boride (HfB), or the like. The thickness of the conductive layer 126 is, for example, about 1 nanometer (nm). The magnetoresistive effect element layer 127 is formed on the upper surface of the conductive layer 126. Note that the upper surface of the conductive layer 126 may be flattened as in S32 of FIG. 27. In this case, the upper surface of each layer included in the magnetoresistive effect element layer 127 provided on the upper surface of the conductive layer 126 is also flattened. Therefore, the characteristics of the magnetoresistive effect element layer 127 are improved.

Next, the annealing treatment is performed on the magnetoresistive effect element layer 127 as in the formation of the first-stage stacked structure. The annealing treatment is performed, for example, at 300° C. to 400° C. for an arbitrary time. Thus, each layer of the magnetoresistive effect element layer 127 is crystallized. Note that the temperature and time for the annealing treatment may be different between a process of forming the first-stage stacked structure and a process of forming the second-stage stacked structure.

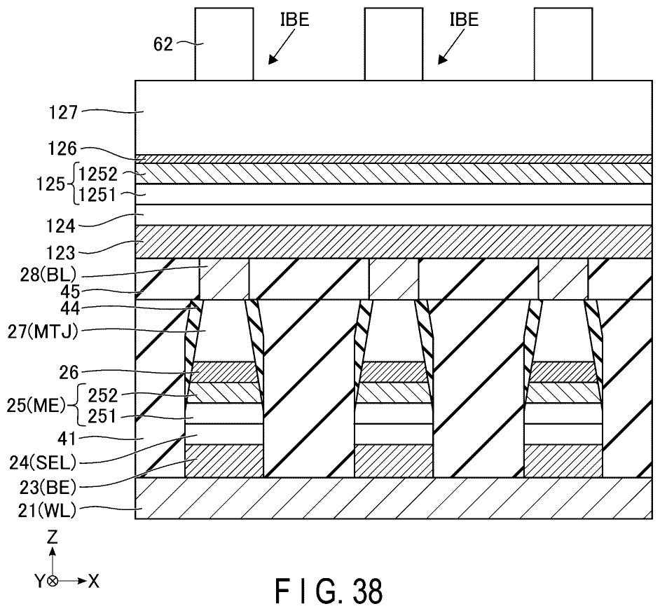

Next, as illustrated in FIG. 38, the plurality of masks 62 are formed as in the first-stage stacked structure.

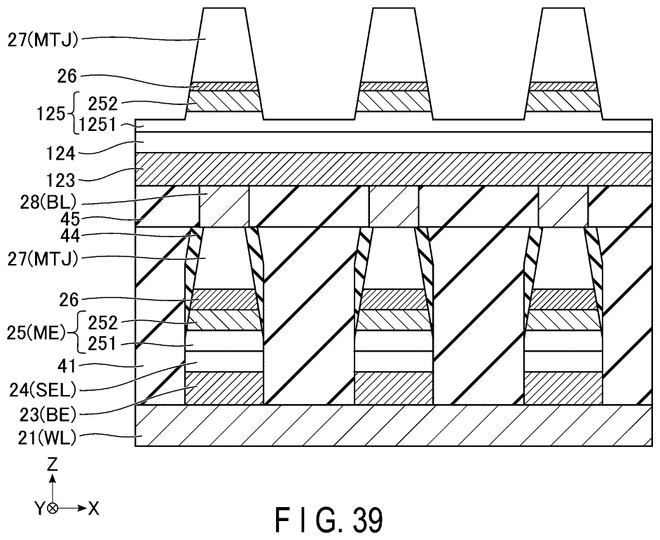

Next, as illustrated in FIG. 38, the conductive layer 1251, the conductive layer 1252, the conductive layer 126, and the magnetoresistive effect element layer 127 are etched by ion beam etching, as in the first-stage stacked structure. Thus, as illustrated in FIG. 39, the plurality of conductors 252, the plurality of conductors 26, and the plurality of MTJ bodies 27 are formed.

Next the insulating layer 144 is formed on the upper surface of the conductive layer 1251, the upper surface of each of the plurality of MTJ bodies 27, and the side surfaces of each of the plurality of conductors 252, the plurality of conductors 26, and the plurality of MTJ bodies 27, as in the first-stage stacked structure.

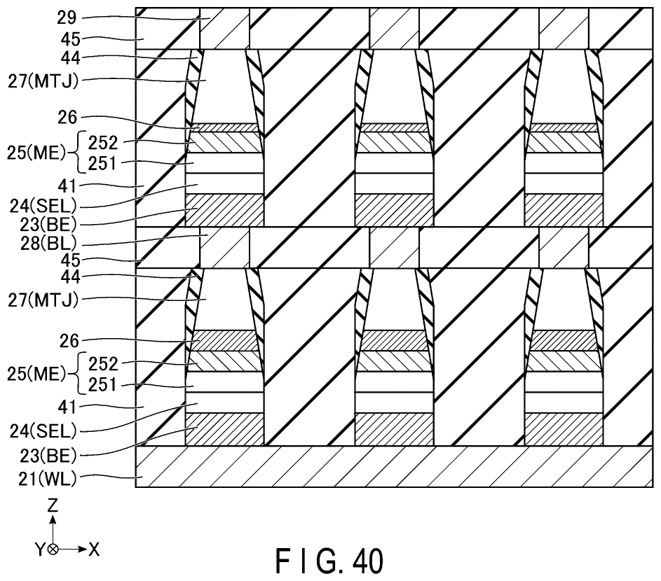

Next, the insulating layer 144 is etched by anisotropic etching as in the first-stage stacked structure. Thus, as illustrated in FIG. 40, the plurality of insulators 44 are formed.

Next, as in the first-stage stacked structure, the portions that are not protected by the insulator 44 are removed by anisotropic etching from the electrode layer 123, the selector layer 124, and the conductive layer 1251, and the plurality of conductors 21 and the insulator 40 located below the portions are exposed. Thus, as illustrated in FIG. 40, the plurality of electrodes 23, the plurality of selector bodies 24, and the plurality of conductors 251 are formed. That is, the plurality of third layer stacks each including the electrode 25, the conductor 26 and the MTJ body 27 are formed.

Next, in S36 of FIG. 27, as illustrated in FIG. 40, the insulator 41 is embedded in the region between two adjacent electrodes 23, the region between two adjacent selector bodies 24, the region between two adjacent conductors 251, and the region between two adjacent insulators 44, as in the first-stage stacked structure.

Next, in S37 of FIG. 27, as illustrated in FIG. 40, the plurality of conductors 29 and the insulator 45 are formed on the upper surfaces of the plurality of third layer stacks, the insulator 41, and the plurality of insulators 44, as in the formation of the first-stage stacked structure.

Next, in S38 of FIG. 27, as illustrated in FIG. 25, the plurality of conductors 21 and the insulator 40 are formed on the upper surfaces of the plurality of conductors 29 and the insulator 45, as in the formation of the first-stage stacked structure.

S35 to S38 of FIG. 27 are performed as described above, thereby forming the second-stage stacked structure. As described above, a configuration corresponding to the memory cell array 10A is formed on the wafer WF. Then, the wafer WF is diced into chips and the magnetic memory device 1A is formed.

The magnetic memory device 1A is formed by the above-described manufacturing process. Note that the above-described manufacturing process is merely an example, and the manufacturing process of the magnetic memory device 1A is not limited thereto. For example, other processing may be inserted between the manufacturing steps, or some processing may be omitted or integrated. In addition, the manufacturing steps may be shuffled within the possible range.

### 2.3 Effects According to Present Embodiment

According to the second embodiment, the same effects as those of the first embodiment are obtained.

In addition, according to the present embodiment, it is possible to make the thickness of the magnetic memory device 1A relatively thin.

### 3. Modification, Etc.

As described above, a magnetic memory device (1) according to an embodiment includes: a first wiring (21) extending in a first direction (X); a second wiring (28) extending in a second direction (Y) intersecting the first direction (X) and provided above the first wiring (21); a first memory cell (MC) provided between the first wiring (21) and the second wiring (28); a third wiring (21) extending in the first direction (X) and provided above the second wiring (28); and a second memory cell (MC) provided between the second wiring (28) and the third wiring (21). The first memory cell (MC) includes a first selector body (24), a first conductor (26), and a first MTJ body (27) provided on an upper surface of the first conductor (26). The second memory cell (MC) includes a second selector body (24), a second conductor (26), and a second MTJ body (27) provided on an upper surface of the second conductor (26). The upper surface of the first conductor (26) is flattened.

Note that the embodiment is not limited to the above-described embodiment, and various modifications are possible.

In addition, in the flowchart described in the above embodiment, the order of the processing can be shuffled to the extent possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a first wiring extending in a first direction;
a second wiring extending in a second direction intersecting the first direction and provided above the first wiring;
a first memory cell including a first selector body, a first conductor, and a first MTJ body provided on an upper surface of the first conductor, the first memory cell being provided between the first wiring and the second wiring;
a third wiring extending in the first direction and provided above the second wiring; and
a second memory cell including a second selector body, a second conductor, and a second MTJ body provided on an upper surface of the second conductor, the second memory cell being provided between the second wiring and the third wiring,
wherein the upper surface of the first conductor is flattened.

2. The device according to claim 1, wherein a thickness of the first conductor is thicker than a thickness of the second conductor.

3. The device according to claim 1, wherein the first conductor and the second conductor include hafnium (Hf) or hafnium boride (HfB).

4. The device according to claim 1, wherein the first selector body is provided below the first MTJ body, and
the second selector body is provided below the second MTJ body.

5. The device according to claim 4, further comprising:
a first electrode provided between the first selector body and the first conductor; and
a second electrode provided between the second selector body and the second conductor.

6. The device according to claim 5, further comprising:
a first insulator covering a side surface of the first selector body and a side surface of the first electrode;
a second insulator covering a side surface of the first conductor and a side surface of the first MTJ body;
a third insulator covering a side surface of the second selector body and a side surface of the second electrode; and
a fourth insulator covering a side surface of the second conductor and a side surface of the second MTJ body.

7. The device according to claim 5, further comprising:
a first insulator covering a side surface of the first electrode, a side surface of the first conductor, and a side surface of the first MTJ body; and
a second insulator covering a side surface of the second electrode, a side surface of the second conductor, and a side surface of the second MTJ body.

8. The device according to claim 5, wherein the first electrode includes a first sub-electrode and a second sub-electrode provided on an upper surface of the first sub-electrode, and
the second electrode includes a third sub-electrode and a fourth sub-electrode provided on an upper surface of the third sub-electrode.

9. The device according to claim 8, wherein the first sub-electrode and the third sub-electrode include at least one element or compound selected from carbon (C) and carbon nitride (CN), and
the second sub-electrode and the fourth sub-electrode include at least one element or compound selected from high melting point metal elements and compounds of high melting point metal elements.

10. The device according to claim 1, wherein
the first MTJ body and the second MTJ body include:
a first ferromagnet;
a second ferromagnet;
a third ferromagnet provided on a side opposite to the first ferromagnet with respect to the second ferromagnet;
a first nonmagnet provided between the first ferromagnet and the second ferromagnet;
a second nonmagnet provided between the second ferromagnet and the third ferromagnet; and
a third nonmagnet provided on a lower surface of the third ferromagnet.

11. The device according to claim 10, wherein the second ferromagnet and the third ferromagnet are antiferromagnetically coupled.

12. The device according to claim 1, wherein the first selector body and the second selector body are two-terminal selector bodies.

13. A method of manufacturing a magnetic memory device, comprising:
forming a structure in which a first selector body and a first electrode are stacked;
forming a first conductive layer on an upper surface of the first electrode;
flattening an upper surface of the first conductive layer;
forming a first magnetoresistive effect element layer on the upper surface of the first conductive layer;
performing a first annealing treatment; and
forming a first conductor and a first MTJ body by removing a part of the first magnetoresistive effect element layer and a part of the first conductive layer.

14. The method according to claim 13, further comprising:
forming a structure in which a second selector body and a second electrode are stacked above the first MTJ body;
forming a second conductive layer on an upper surface of the second electrode;
forming a second magnetoresistive effect element layer on an upper surface of the second conductive layer;
performing a second annealing treatment; and
forming a second conductor and a second MTJ body by removing a part of the second magnetoresistive effect element layer and a part of the second conductive layer.

15. The method according to claim 13, wherein
flattening the upper surface of the first conductive layer includes:
forming a third conductive layer on the upper surface of the first conductive layer;
forming a fourth conductive layer on an upper surface of the third conductive layer; and
flattening the upper surface of the first conductive layer by removing the third conductive layer and the fourth conductive layer using ion beam etching.

16. The method according to claim 13, wherein
forming the first conductive layer includes
forming the first conductive layer including hafnium (Hf) or hafnium boride (HfB).

17. A method of manufacturing a magnetic memory device, comprising:
forming a first selector layer;
forming a first electrode layer on an upper surface of the first selector layer;
forming a first conductive layer on an upper surface of the first electrode layer;
flattening an upper surface of the first conductive layer;
forming a first magnetoresistive effect element layer on the upper surface of the first conductive layer;
performing a first annealing treatment; and
forming a first selector body, a first electrode, a first conductor, and a first MTJ body by removing a part of the first magnetoresistive effect element layer, a part of the first conductive layer, a part of the first electrode layer, and a part of the first selector layer.

18. The method according to claim 17, further comprising:
forming a second selector layer above the first MTJ body;
forming a second electrode layer on an upper surface of the second selector layer;
forming a second conductive layer on an upper surface of the second electrode layer;
forming a second magnetoresistive effect element layer on an upper surface of the second conductive layer;
performing a second annealing treatment; and
forming a second selector body, a second electrode, a second conductor, and a second MTJ body by removing a part of the second magnetoresistive effect element layer, a part of the second conductive layer, a part of the second electrode layer, and a part of the second selector layer.

19. The method according to claim 17, wherein
flattening the upper surface of the first conductive layer includes:
forming a third conductive layer on the upper surface of the first conductive layer;
forming a fourth conductive layer on an upper surface of the third conductive layer; and
flattening the upper surface of the first conductive layer by removing the third conductive layer and the fourth conductive layer using ion beam etching.

20. The method according to claim 17, wherein
forming the first conductive layer includes
forming the first conductive layer including hafnium (Hf) or hafnium boride (HfB).
